(19) United States
(12) Patent Application Publication
(10) Pub. No.: US 2025/0359016 A1
(43) Pub. Date: Nov. 20, 2025

(54) SEMICONDUCTOR DEVICE AND METHOD FOR FABRICATING THE SAME

(71) Applicant: SK hynix Inc., Gyeonggi-do (KR)

(72) Inventors: Kang Sik CHOI, Gyeonggi-do (KR); Jeong Hoon KWON, Gyeonggi-do (KR); Jun Ha KWAK, Gyeonggi-do (KR); Jung Won SEO, Gyeonggi-do (KR); Dong II SONG, Gyeonggi-do (KR)

(21) Appl. No.: 19/210,074

(22) Filed: May 16, 2025

(30) Foreign Application Priority Data
May 16, 2024 (KR) 10-2024-0063738
May 14, 2025 (KR) 10-2025-0062273

(51) Int. Cl. H10B 12/00

(52) U.S. Cl. CPC H10B 12/30; H10B 12/03; H10B 12/05

(57) ABSTRACT

A semiconductor device including high-integrated memory cells and a method for fabricating the semiconductor device are provided. The semiconductor device includes vertical and horizontal arrangements of nano sheets including horizontal sheets, which include protruding sheet nodes, and tapered sheets, which are continuous in a first horizontal direction from the horizontal sheets, a vertical arrangement of first conductive lines that surround portions of the horizontal sheets in the horizontal arrangement and are oriented in a second horizontal direction, first contact nodes covering the protruding sheet nodes of the horizontal sheets, a horizontal arrangement of second conductive lines that cover the first contact nodes and are oriented in a vertical direction, supporters that are disposed between the second conductive lines in the horizontal arrangement and are oriented in the vertical direction, and data storage elements coupled to the tapered sheets.

### CROSS-REFERENCE TO RELATED APPLICATIONS

The present application claims priority under 35 U.S.C 119(a) to Korean Patent Application Nos. 10-2024-0063738 and 10-2025-0062273, filed on May 16, 2024, and May 14, 2025, respectively, which are incorporated herein by reference in its entirety.

### BACKGROUND

### 1. Field

Various embodiments of the present disclosure relate generally to a semiconductor device, and more particularly, to a semiconductor device including three-dimensional (3D) memory cells, and a method for fabricating the semiconductor device.

### 2. Description of the Related Art

Recently, in order to cope with the large capacity and miniaturization of a memory device, a three-dimensional (3D) memory device in which a plurality of memory cells are stacked has been proposed.

### SUMMARY

Embodiments of the present disclosure are directed to a 3D semiconductor device (hereinafter simply referred to as semiconductor device) including high-integrated memory cells, and a method for fabricating the semiconductor device.

In accordance with an embodiment of the present disclosure, a semiconductor device may include vertical and horizontal arrangements of nano sheets including horizontal sheets, which include protruding sheet nodes, and tapered sheets, which are continuous in a first horizontal direction from the horizontal sheets; a vertical arrangement of first conductive lines that surround portions of the horizontal sheets in the horizontal arrangement and are oriented in a second horizontal direction; first contact nodes covering the protruding sheet nodes of the horizontal sheets; a horizontal arrangement of second conductive lines that cover the first contact nodes and are oriented in a vertical direction; supporters that are disposed between the second conductive lines in the horizontal arrangement and are oriented in the vertical direction; and data storage elements coupled to the tapered sheets.

In accordance with an embodiment of the present disclosure, a method for fabricating a semiconductor device may include forming a vertical stack of mold layers; forming sacrificial isolation layers between the mold layers in the vertical stack; replacing one-side edges of the sacrificial isolation layers with supporters; forming vertical and horizontal arrangements of pre-nano sheet layers including horizontal sheets including protruding edges, which contact the supporters through recessing of the mold layers, and body sheets which are continuous from the horizontal sheets; replacing the sacrificial isolation layers with inter-cell dielectric layers; forming first conductive lines that surround portions of the horizontal sheets between the inter-cell dielectric layers and the supporters and are oriented horizontally; forming protruding sheet nodes between the supporters by cutting protruding edges of the horizontal sheets; and forming a horizontal arrangement of second conductive lines that are electrically coupled to the protruding sheet nodes and are vertically oriented between the supporters in a direction intersecting the first conductive lines. In accordance with an embodiment of the present disclosure, a semiconductor device may include a 3D arrangement of nano sheets, each nano sheet including a horizontal sheet having a protruding sheet node at a first end thereof, and a tapered sheet continuous in a first horizontal direction from a second end of the horizontal sheet that is opposite to the first end; a vertical arrangement of first conductive lines, each of the first conductive lines surrounding a portion of each horizontal sheet and extending in a second horizontal direction; first contact nodes covering the protruding sheet nodes of the horizontal sheet; a horizontal arrangement of second conductive lines, each second conductive line extending in a vertical direction and covering a corresponding one of the first contact nodes; a plurality of supporters, each supporter being disposed between the second conductive lines; and a plurality of data storage elements, each data storage element being coupled to a tapered sheet of a corresponding one of the nano sheets.

These and other features and advantages of the embodiments of the present disclosure will become apparent to those skilled in the art from the following detailed description in conjunction with the following drawings.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell illustrated in FIG. 1A.

FIG. 2 is a schematic perspective view illustrating a semiconductor device in accordance with an embodiment of the present disclosure.

FIG. 3A is a schematic cross-sectional view of a vertical arrangement of memory cells illustrated in FIG. 2.

FIG. 3B is a schematic perspective view illustrating first conductive lines illustrated in FIG. 2.

FIG. 3C is a schematic perspective view illustrating a first spacer illustrated in FIG. 2.

FIG. 3D is a schematic perspective view illustrating a second spacer illustrated in FIG. 2.

FIG. 3E is a schematic perspective view illustrating supporters illustrated in FIG. 2.

FIG. 4A is a schematic plan view of a semiconductor device in accordance with an embodiment of the present disclosure.

FIG. 4B is a schematic cross-sectional view of the semiconductor device taken along line A-A′ illustrated in FIG. 4A.

FIG. 4C is a schematic cross-sectional view of the semiconductor device taken along line B-B′ illustrated in FIG. 4A.

FIG. 4D is a cross-sectional view of the semiconductor device taken along line C-C′ illustrated in FIG. 4A.

FIGS. 5A to 26B illustrate various views of a semiconductor device formed utilizing a method for fabricating the semiconductor device in accordance with an embodiment of the present disclosure.

FIG. 27 is a schematic cross-sectional view of a semiconductor device according to another embodiment.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the present disclosure.

The following embodiment relates to three-dimensional memory cells, in which memory cells are vertically stacked to increase memory cell density and reduce parasitic capacitance.

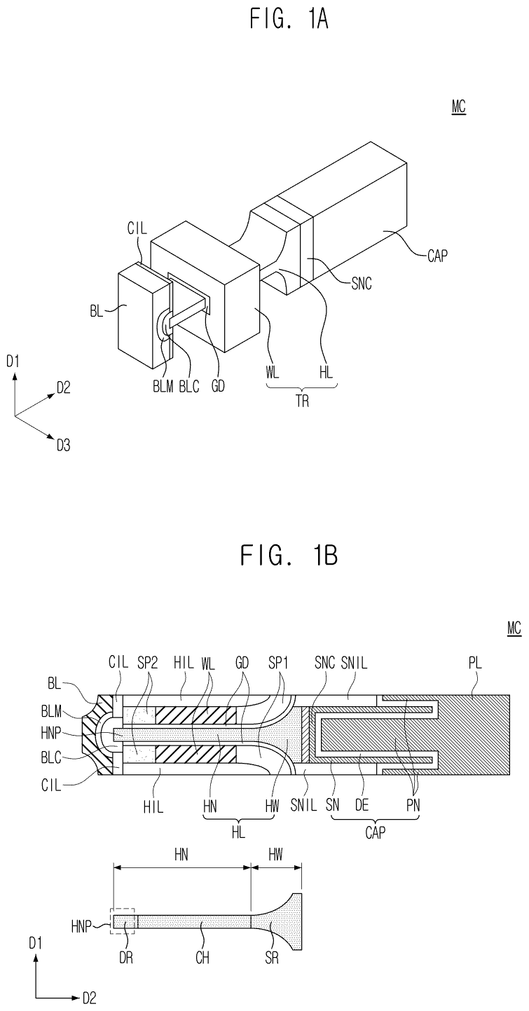

FIG. 1A is a schematic perspective view illustrating a memory cell MC in accordance with an embodiment of the present disclosure. FIG. 1B is a schematic cross-sectional view of the memory cell MC illustrated in FIG. 1A.

Referring to FIGS. 1A and 1B, the memory cell MC may include a switching element TR and a data storage element CAP.

The switching element TR may control a voltage or a current supply to the data storage element CAP during a data write and/or a data read operation performed on the data storage element CAP. The switching element TR may include a nano sheet HL, a nano sheet dielectric layer GD, and a first conductive line WL. The first conductive line WL may include a horizontal conductive line or a horizontal word line, and the nano sheet HL may include an active layer. The switching element TR may include a transistor, and in this case, the first conductive line WL may serve as a gate electrode. The switching element TR may also be referred to as a “nano sheet transistor”, a “cell transistor”, an “access element” or a “selection element”. The first conductive line WL may also be referred to as a “horizontal gate electrode” or a “horizontal word line”.

The nano sheet HL may include a horizontal sheet HN and a tapered sheet HW, which are horizontally disposed along a second direction D2. The horizontal sheet HN and the tapered sheet HW may have an integral structure that is continuous along the second direction D2.

The tapered sheet HW may have a thickness that gradually increases in the second direction D2 from the horizontal sheet HN toward the data storage element CAP between the horizontal sheet HN and the data storage element CAP. An average vertical height or thickness of the tapered sheet HW in a first direction D1 may be greater than an average vertical height or thickness of the horizontal sheet HN. A horizontal length of the tapered sheet HW in the second direction D2 may be less than a horizontal length of the horizontal sheet HN. The tapered sheet HW may be referred to also as a short sheet, and the horizontal sheet HN may be referred to also as a long sheet.

Upper (also referred to as top) and lower (also referred to as bottom) surfaces of the horizontal sheet HN may include flat surfaces. A cross-section of the horizontal sheet HN may have a flat-plate shape. Upper and lower surfaces of the tapered sheet HW may have tapered profiles. That is, a cross-section of the tapered sheet HW may have a fan-like shape. The horizontal sheet HN may be referred to also as a “flat plate-shaped sheet”, and the tapered sheet HW may be referred to also as a “fan-like shaped sheet”. An outside surface of the tapered sheet HW that contacts the data storage element CAP may have a flat side shape. The horizontal sheet HN may include a protruding sheet node HNP.

The nano sheet HL may include a first doped region DR, a second doped region SR, and a channel CH disposed between the first and second doped regions DR and SR. The first doped region DR may be electrically coupled to a second conductive line BL, and the second doped region SR may be electrically coupled to the data storage element CAP. The first doped region DR and the channel CH of the nano sheet HL may be formed in the horizontal sheet HN, and the second doped region SR of the nano sheet HL may be formed in the tapered sheet HW. The first doped region DR may be formed in the protruding sheet node HNP.

The second conductive line BL may vertically extend in the first direction D1, the nano sheet HL may horizontally extend in the second direction D2 that intersects the first direction D1, and the first conductive line WL may horizontally extend in a third direction D3 that intersects the first direction D1 and the second direction D2. The first direction D1 may be a vertical direction, the second direction D2 may be a first horizontal direction, and the third direction D3 may be a second horizontal direction. The nano sheet HL may extend in the first horizontal direction, i.e., the second direction D2, and the first conductive line WL may extend in the second horizontal direction, i.e., the third direction D3. The nano sheet HL may be referred to as a “horizontal layer” or “nano ribbon”.

The nano sheet HL may be horizontally oriented in the second direction D2 from the second conductive line BL. The first doped region DR, the channel CH and the second doped region SR may be horizontally formed in the second direction D2. A height of the second doped region SR in the first direction D1 may be greater than a height of the channel CH in the first direction D1. A length of the second doped region SR in the second direction D2 may be less than a length of the channel CH in the second direction D2. Lengths of the channel CH and the second doped region SR in the third direction D3 may be equal to each other. An average length of the first doped region DR in the third direction D3 may be less than lengths of the channel CH and second doped region SR in the third direction D3.

The nano sheet HL may include a semiconductive material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), InSnZnO, ZnSnO, or a combination thereof. In some embodiments, the nano sheet HL may include conductive metal oxide. In some embodiments, the nano sheet HL may include a two-dimensional material, for example, molybdenum disulfide (MoS₂), tungsten disulfide (WS₂), or molybdenum selenide (MoSe₂).

When the nano sheet HL is formed of the oxide semiconductor material, the channel CH may also be formed of the oxide semiconductor material, and the first and second doped regions DR and SR may be omitted. The nano sheet HL may also be referred to as an “active layer” or a “thin body”.

The channel CH may not contain any dopants and may be referred to as being undoped. The first and second doped regions DR and SR may be doped with an impurity of the same conductivity type. For example, each of the first and second doped regions DR and SR may be doped with an N-type conductive impurity or a P-type conductive impurity. Each of the first and second doped regions DR and SR may include at least one impurity selected from among arsenic (As), phosphorus (P), boron (B), indium (In), and combinations thereof. The first doped region DR may be coupled to the second conductive line BL, and the second doped region SR may be coupled to the data storage element CAP. One of the first and second doped regions DR and SR may be a drain region, and the other may be a source region.

The first conductive line WL may have a gate-all-around (GAA) structure. For example, the first conductive line WL may surround a portion of the nano sheet HL and extend in the third direction D3. The nano sheet dielectric layer GD may be formed between the nano sheet HL and the first conductive line WL. The nano sheet dielectric layer GD may surround all surfaces of the channel CH of the nano sheet HL. The first conductive line WL may surround the channel CH of the nano sheet HL on the nano sheet dielectric layer GD.

The first conductive line WL may include a metal-based material, a semiconductive material, or a combination thereof. The first conductive line WL may include molybdenum, molybdenum nitride, ruthenium, titanium nitride, tungsten, polysilicon, or a combination thereof. For example, the first conductive line WL may include a TiN/W stack in which titanium nitride and tungsten are sequentially stacked. The first conductive line WL may include an N-type work function material or a P-type work function material. The N-type work function material may have a low work function of approximately 4.5 eV or less, and the P-type work function material may have a high work function of approximately 4.5 eV or greater. The first conductive line WL may include a stack of a low work function material and a high work function material.

The nano sheet dielectric layer GD may be disposed between the nano sheet HL and the first conductive line WL. The nano sheet dielectric layer GD may be referred to also as a “gate dielectric layer” or a “channel-side dielectric layer”. The nano sheet dielectric layer GD may include, for example, silicon oxide, silicon nitride, metal oxide, metal oxynitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by thermal oxidation of the nano sheet HL. In some embodiments, forming the nano sheet dielectric layer GD may include depositing a nano sheet dielectric material on the nano sheet HL and oxidizing the surfaces of the nano sheet HL.

The second conductive line BL may be vertically oriented in the first direction D1. The second conductive line BL may include a bit line. The second conductive line BL may be referred to also as a “vertical conductive line”, a “vertically-oriented bit line”, a “vertically-extending bit line”, or a “pillar-shaped bit line”. The second conductive line BL may include a conductive material. The second conductive line BL may include, for example, a silicon-based material, a metal-based material, or a combination thereof. The second conductive line BL may include polysilicon, metal, metal nitride, metal silicide, or a combination thereof. The second conductive line BL may include polysilicon, titanium nitride, tungsten, or a combination thereof. For example, the second conductive line BL may include a titanium nitride/tungsten (TiN/W) stack in which titanium nitride and tungsten are sequentially stacked. The second conductive line BL may be electrically coupled to the first doped region DR of the nano sheet HL.

The data storage element CAP may include a memory element such as a capacitor. The data storage element CAP may be horizontally disposed in the second direction D2 from the switching element TR. The data storage element CAP may be electrically coupled to the second doped region SR of the nano sheet HL.

The data storage element CAP may include a first electrode SN, a second electrode PN disposed over the first electrode SN, and a dielectric layer DE disposed between the first electrode SN and the second electrode PN. The first electrode SN may horizontally extend in the second direction D2 from the nano sheet HL. The first electrode SN, the dielectric layer DE and the second electrode PN may be horizontally disposed in the second direction D2. The first electrode SN may be a storage node, and the second electrode PN may be a plate node.

The first electrode SN may include an inner space and a plurality of outer surfaces. The inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1. The horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region SR of the nano sheet HL. The second electrode PN of the data storage element CAP may be coupled to a common plate PL.

The data storage element CAP may have a three-dimensional structure. The first electrode SN may have a three-dimensional structure, which may have a horizontal three-dimensional structure that is oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region SR of the nano sheet HL. The dielectric layer DE and the second electrode PN may be disposed on the cylindrical inner surfaces and cylindrical outer surfaces of the first electrode SN. The first electrode SN may include a metallic cylinder.

In some embodiments, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may each include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode PN may also include a combination of a metal-based material and a silicon-based material.

The dielectric layer DE may be referred to also as a “capacitor dielectric layer” or a “memory layer”. The dielectric layer DE may include, for example, silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), strontium titanium oxide (SrTiO₃), or a combination thereof. In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer”. In some embodiments, the dielectric layer DE may be formed of hafnium (Hf)-based oxide.

The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”.

In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Because the dielectric layer DE includes a high band gap material, leakage current may be suppressed. The high band gap material may be thinner than the high-k material.

In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, an HAHA (HfO₂/Al₂O₃/HfO₂/Al₂O₃) stack, an HAHAH (HfO₂/Al₂O₃/HfO₂/Al₂O₃/HfO₂) stack, an HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, an HZHZ (HfO₂/ZrO₂/HfO₂/ZrO₂) stack, an AHZAZHA (Al₂O₃/HfO₂/ZrO₂/Al₂O₃/ZrO₂/HfO₂/Al₂O₃) stack, or a ZHZAZHZAT (ZrO₂/HfO₂/ZrO₂/Al₂O₃/ZrO₂/HfO₂/ZrO₂/Al₂O₃/TiO₂) stack. In the above-described stack structures, aluminum oxide (Al₂O₃) may be thinner than zirconium oxide (ZrO₂) and hafnium oxide (HfO₂).

In some embodiments, the dielectric layer DE may include a high-k material and a high band gap material. The dielectric layer DE may have a laminated structure in which a plurality of high-k materials and a plurality of high band gap materials are stacked or an intermixed structure in which a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, the data storage element CAP may further include a plurality of interface control layers to alleviate leakage current. The interface control layers may each include titanium oxide (TiO₂), tantalum oxide (Ta₂O₅), niobium oxide (Nb₂O₅), niobium nitride (NbN), niobium oxynitride (NbON), or a combination thereof. The data storage element CAP may include a first interface control layer, a second interface control layer, or a combination thereof. The first interface control layer and the second interface control layer may be conductive or dielectric. The first interface control layer may be formed between the first electrode SN and the dielectric layer DE, and the second interface control layer may be formed between the dielectric layer DE and the second electrode PN. The first interface control layer and the second interface control layer may be the same material or different materials. For example, a structure of the data storage element CAP in which the first interface control layer, the dielectric layer DE and the second interface control layer are sequentially stacked may include an NZHZAZHZATN (Nb₂O₅/ZrO₂/HfO₂/ZrO₂/Al₂O₃/ZrO₂/HfO₂/ZrO₂/Al₂O₃/TiO₂/Nb₂O₅) stack.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first doped region DR of the nano sheet HL and the second conductive line BL. The first contact node BLC may include metal, a metal-based material, or a semiconductive material. For example, the first contact node BLC may include titanium, titanium nitride, tungsten, or a combination thereof. In addition, the first contact node BLC may include doped polysilicon, and the first doped region DR may include an impurity diffused from the first contact node BLC. The first contact node BLC may cover the protruding sheet node HNP of the horizontal sheet HN.

The second contact node SNC may be disposed between the second doped region SR of the nano sheet HL and the first electrode SN of the data storage element CAP. The second contact node SNC may include a metal-based material or a semiconductive material. For example, the second contact node SNC may include titanium, titanium nitride, tungsten, or a combination thereof. In addition, the second contact node SNC may include doped polysilicon, and the second doped region SR may include an impurity diffused from the second contact node SNC. A height of the first contact node BLC in the first direction D1 may be less than a height of the second contact node SNC in the first direction D1. The height of the first contact node BLC in the first direction D1 may be greater than or equal to a height of the channel CH in the first direction D1.

In some embodiments, the second contact node SNC may be selectively grown from the tapered sheet HW of the nano sheet HL. The second contact node SNC may be formed by selective epitaxial growth (SEG). For example, the second contact node SNC may be a silicon epitaxial layer formed by the SEG. The second contact node SNC may be a doped silicon epitaxial layer.

The nano sheet HL may include a first edge and a second edge. The first edge may refer to a portion of the first doped region DR or a portion of the horizontal sheet HN, which is electrically coupled to the second conductive line BL, and the second edge may refer to a portion of the second doped region SR or a portion of the tapered sheet HW, which is electrically coupled to the first electrode SN of the data storage element CAP.

The memory cell MC may further include an ohmic contact layer BLM disposed between the first contact node BLC and the second conductive line BL. The ohmic contact layer BLM may include a metal silicide. The ohmic contact layer BLM may cover at least a portion of the first contact node BLC. A contact isolation layer CIL may be formed on upper (also referred to as top) and lower (also referred to as bottom) surfaces of the first contact node BLC in the first direction D1. The contact isolation layer CIL may include a dielectric material.

The memory cell MC may further include a first spacer SP1 and a second spacer SP2. The first spacer SP1 may be disposed between the first conductive line WL and the first electrode SN of the data storage element CAP. The second spacer SP2 may be disposed between the first conductive line WL and the second conductive line BL. The first and second spacers SP1 and SP2 may each include a dielectric material. The first and second spacers SP1 and SP2 may each include silicon oxide, silicon nitride, or a combination thereof. The first spacer SP1 may be referred to as a “word line spacer”, and the second spacer SP2 may be referred to as a “bit line spacer”.

The first spacer SP1 may surround the second doped region SR of the nano sheet HL, that is, at least a portion of the tapered sheet HW, and the second spacer SP2 may surround the first doped region DR of the nano sheet HL, that is, a portion of the horizontal sheet HN. The first and second spacers SP1 and SP2 may be disposed on both sidewalls of the first conductive line WL. The first and second spacers SP1 and SP2 may extend in the third direction D3. The contact isolation layer CIL may be disposed between the second conductive line BL and the second spacer SP2.

The first conductive line WL may be disposed between inter-cell horizontal dielectric layers HIL that are vertically stacked. The first spacer SP1 may cover one side of the inter-cell horizontal dielectric layers HIL. The second spacer SP2 may be disposed between the inter-cell horizontal dielectric layers HIL. The inter-cell horizontal dielectric layers HIL may extend in the third direction D3. The inter-cell horizontal dielectric layers HIL may each include silicon oxide, silicon nitride, or a combination thereof.

The first spacer SP1 may have a cup shape covering a first side of the inter-cell horizontal dielectric layer HIL. The first spacer SP1 extending in the first direction D1 and the third direction D3 may have a frame structure surrounding a portion of the tapered sheet HW.

The second spacer SP2 extending in the first direction D1 and the third direction D3 may have a frame structure surrounding a portion of the horizontal sheet HN.

The first electrode SN of the data storage element CAP may be disposed between inter-storage node dielectric layers SNIL. A horizontal length of the inter-storage node dielectric layer SNIL may be less than a horizontal length of the first electrode SN.

From another perspective, the memory cell MC may have a 1T-1C structure, where 1T may refer to one switching element TR, and 1C may refer to one data storage element CAP. When the memory cell MC is a DRAM cell having the 1T-1C structure, 1T may refer to one cell transistor, and 1C may refer to one capacitor. Accordingly, a gate of the cell transistor may be a word line, a drain region of the cell transistor may be coupled to a bit line, and a source region of the cell transistor may be coupled to the capacitor. The bit line may correspond to the second conductive line BL of FIGS. 1A and 1B, the word line may correspond to the first conductive line WL of FIGS. 1A and 1B, and the capacitor may correspond to the data storage element CAP of FIGS. 1A and 1B. In addition, the drain region of the cell transistor may correspond to the first doped region DR of FIGS. 1A and 1B, and the source region of the cell transistor may correspond to the second doped region SR of FIGS. 1A and 1B.

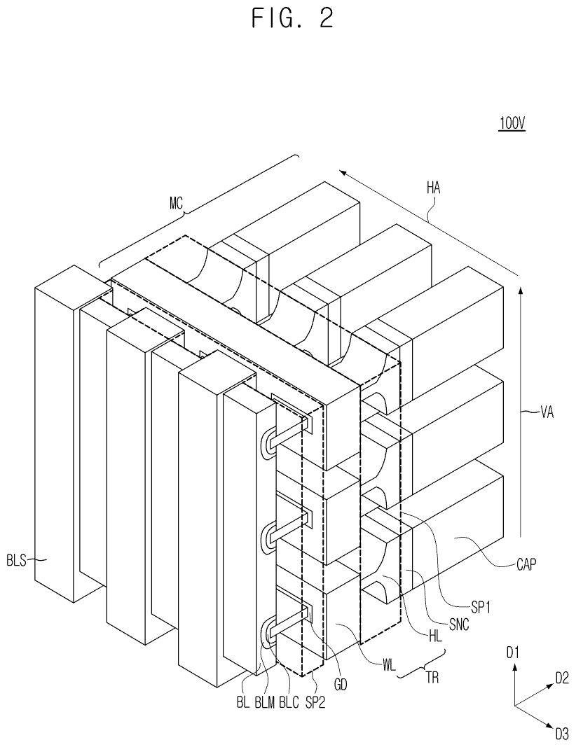

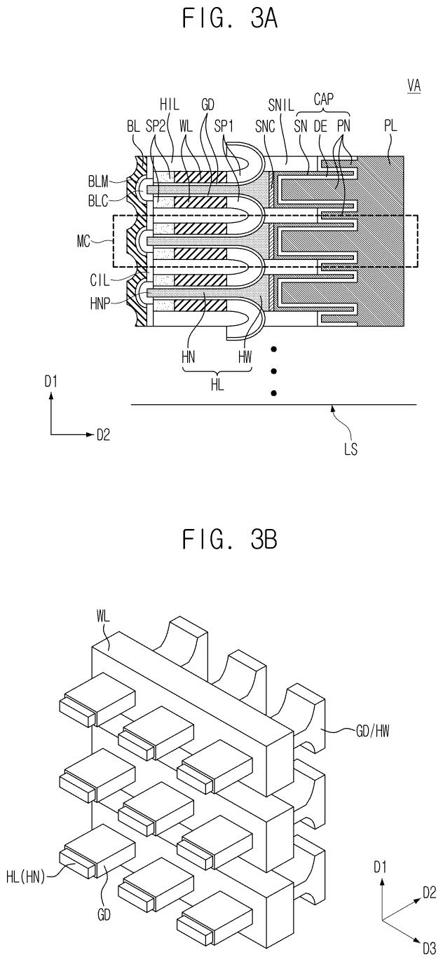

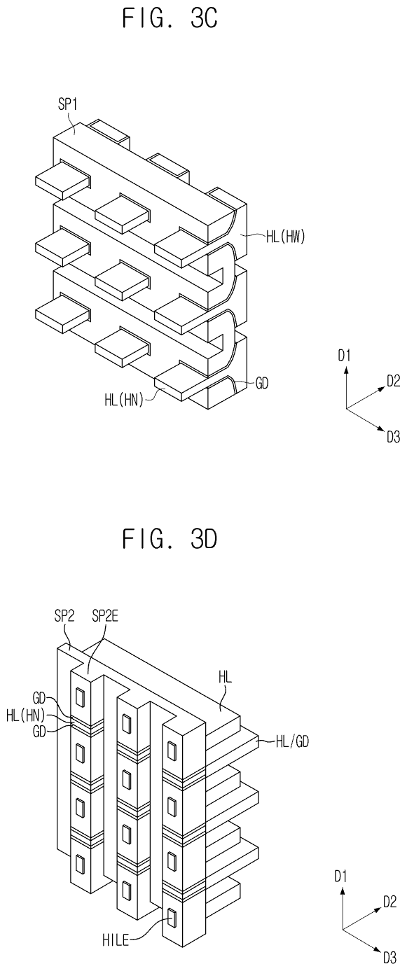

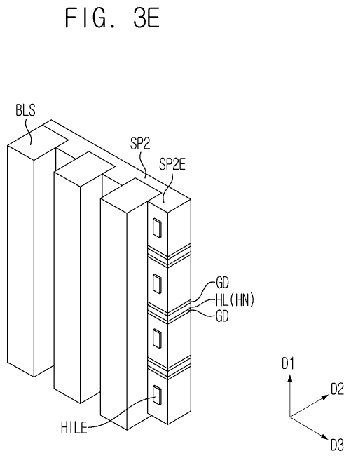

FIG. 2 is a schematic perspective view illustrating a semiconductor device 100V in accordance with an embodiment of the present disclosure. FIG. 3A is a schematic cross-sectional view of a vertical arrangement VA of memory cells MC illustrated in FIG. 2. FIG. 3B is a schematic perspective view illustrating first conductive lines WL illustrated in FIG. 2. FIG. 3C is a schematic perspective view illustrating a first spacer SP1 illustrated in FIG. 2. FIG. 3D is a schematic perspective view illustrating a second spacer SP2 illustrated in FIG. 2. FIG. 3E is a schematic perspective view illustrating supporters BLS illustrated in FIG. 2.

Referring to FIGS. 2 to 3E, the semiconductor device 100V may include a three-dimensional array of the memory cells MC described above with reference to FIGS. 1A and 1B. Detailed descriptions of each of the memory cells MC are provided above with reference to FIGS. 1A and 1B.

Referring to FIGS. 2 to 3D, the semiconductor device 100V may include a horizontal arrangement HA and a vertical arrangement VA of the memory cells MC disposed over a lower structure LS. The memory cells MC in the horizontal arrangement HA may be horizontally spaced apart in a third direction D3. The memory cells MC in the vertical arrangement VA may be vertically stacked in a first direction D1. The memory cells MC in the horizontal arrangement HA may be vertically stacked in the first direction D1. The vertical arrangement VA of the memory cells MC may refer to a structure in which the horizontal arrangements HA of the memory cells MC are vertically stacked in the first direction D1. The semiconductor device 100V may include a horizontal arrangement of vertical conductive lines in which the vertical conductive lines are arranged spaced apart from each other at a regular interval in the third direction D3. The horizontal arrangement of the vertical conductive lines may include the horizontal arrangement HA of second conductive lines BL. The semiconductor device 100V may include a vertical arrangement of horizontal conductive lines in which the horizontal conductive lines are arranged in the first direction D1. The vertical arrangement of the horizontal conductive lines may include the vertical arrangement VA of the first conductive lines WL.

The memory cells MC in each horizontal arrangement HA may be coupled to different second conductive lines BL and share one first conductive line WL. The memory cells MC in each vertical arrangement VA may share different first conductive lines WL and be coupled to one second conductive line BL. The supporters BLS may be disposed between the second conductive lines BL adjacent to each other in the third direction D3.

The vertical arrangement VA may constitute a plurality of tiers. Each of the inter-cell horizontal dielectric layers HIL may be formed between the memory cells MC in the vertical arrangement VA. Each of the inter-cell horizontal dielectric layers HIL may be disposed between the first conductive lines WL in the first direction D1. Referring to FIGS. 3D and 3E, the inter-cell horizontal dielectric layers HIL may include protrusions HILE disposed on outer walls of the supporters BLS.

Each of the memory cells MC may include a switching element TR and a data storage element CAP. The switching element TR may include a nano sheet HL, a nano sheet dielectric layer GD, and the first conductive line WL. The nano sheet HL may include a first doped region DR, a second doped region SR, and a channel CH disposed between the first and second doped regions DR, SR. A first contact node BLC may be formed between the first doped region DR of the nano sheet HL and the second conductive line BL. A second contact node SNC may be formed between the second doped region SR of the nano sheet HL and the data storage element CAP. The nano sheet HL may be surrounded by the nano sheet dielectric layer GD. The first conductive line WL may extend in the third direction D3 and may also surround the channels CH of the nano sheets HL on the nano sheet dielectric layer GD. Each of the contact isolation layers CIL may be formed between the first contact nodes BLC in the first direction D1. The memory cell MC may further include an ohmic contact layer BLM disposed between the first contact node BLC and the second conductive line BL. The ohmic contact layer BLM may include metal silicide.

The semiconductor device 100V may include the horizontal arrangement HA and vertical arrangement VA of the nano sheets HL. The semiconductor device 100V may include the horizontal arrangement HA and vertical arrangement VA of the switching elements TR. The semiconductor device 100V may include the horizontal arrangement HA of the second conductive lines BL. The semiconductor device 100V may include the vertical arrangement VA of the first conductive lines WL. The semiconductor device 100V may include the horizontal arrangement HA and vertical arrangement VA of the data storage elements CAP. Each of the inter-storage node dielectric layers SNIL may be formed between first electrodes SN of the data storage elements CAP in the first direction D1.

The semiconductor device 100V may further include the first spacer SP1 and the second spacer SP2, which are described above with reference to FIG. 1B. The first spacer SP1 may have a multi-layer structure, and the second spacer SP2 may have a single-layer structure. The first spacer SP1 may be disposed between the first conductive line WL and the first electrode SN of the data storage element CAP. The second spacer SP2 may be disposed between the first conductive line WL and the second conductive line BL. The first and second spacers SP1 and SP2 may each include a dielectric material. The first and second spacers SP1 and SP2 may each include silicon oxide, silicon nitride, or a combination thereof. The second spacer SP2 may include extension portions SP2E disposed on upper and lower surfaces of the first doped regions DR of horizontal sheets HN of the nano sheets HL in the horizontal arrangement HA. The extension portions SP2E of the second spacer SP2 may not cover the side surfaces of the first doped regions DR.

Referring back to FIGS. 3C and 3D, the first spacer SP1 may vertically extend in the first direction D1 and may also surround the tapered sheets HW in the vertical arrangement VA. In addition, the first spacer SP1 may horizontally extend in the third direction D3 and may also surround the tapered sheets HW in the horizontal arrangement HA.

The first spacer SP1 may surround second doped regions SR of the tapered sheets HW of the nano sheets HL in the horizontal arrangement HA. The first conductive lines WL may surround the channels CH of the horizontal sheets HN of the nano sheets HL in the horizontal arrangement HA. The second spacer SP2 may surround the first doped regions DR of the horizontal sheets HN of the nano sheets HL in the horizontal arrangement HA. Specifically, the first spacer SP1 may extend in the first direction D1 and the third direction D3 and may also surround the second doped regions SR of the nano sheets HL in the horizontal arrangement HA. The second spacer SP2 may extend in the first direction D1 and the third direction D3 and may also surround the first doped regions DR of the nano sheets HL in the horizontal arrangement HA. The first conductive lines WL may extend in the third direction D3 and may also surround the channels CH of the nano sheets HL in the horizontal arrangement HA.

In this way, the first conductive lines WL, the first spacer SP1 and the second spacer SP2 may surround the nano sheets HL disposed at the same horizontal level. The first spacer SP1 and the second spacer SP2 may each have a frame structure. The first spacer SP1 having the frame structure may surround all second doped regions SR of the nano sheets HL in the horizontal arrangement HA and the vertical arrangement VA. The second spacer SP2 having the frame structure may surround all first doped regions DR of the nano sheets HL in the horizontal arrangement HA and the vertical arrangement VA.

Referring back to FIGS. 3D and 3E, the extension portions SP2E of the second spacer SP2 may surround the protrusions HILE of the inter-cell horizontal dielectric layers HIL.

Each of the supporters BLS may be disposed between the second conductive lines BL adjacent to each other in the third direction D3. The supporters BLS may vertically extend in the first direction D1. The supporters BLS may support portions of the nano sheets HL. The supporters BLS may each include a dielectric material. The supporters BLS may each include silicon nitride. The second conductive lines BL may be formed to be self-aligned with the supporters BLS. The second conductive lines BL may be referred to also as “Self-Aligned Bit Lines (SABL)”. The second conductive lines BL may cover the first contact nodes BLC. Outer surfaces of the second conductive lines BL may have non-linear profiles. In another embodiment, the outer surfaces of the second conductive lines BL may each have a linear profile.

The extension portions SP2E of the second spacer SP2 may cover inner walls of the supporters BLS while the outer walls of the supporters BLS may contact the second conductive lines BL.

Referring to FIGS. 1A to 3E, the semiconductor device 100V may include the vertical arrangement VA and horizontal arrangement HA of the nano sheets HL each including the horizontal sheet HN including the protruding sheet node HNP and the tapered sheet HW that is continuous in the first horizontal direction D2 from the horizontal sheet HN, the vertical arrangement VA of the first conductive lines WL that are oriented in the second horizontal direction D3 and also surround portions of the horizontal sheets HN in the horizontal arrangement HA, the first contact nodes BLC covering the protruding sheet nodes HNP of the horizontal sheets HN, the horizontal arrangement HA of the second conductive lines BL that are oriented in the vertical direction D1 and also covering the first contact nodes BLC, the supporters BLS that are disposed between the second conductive lines BL in the horizontal arrangement HA and are oriented in the vertical direction D1, and the data storage elements CAP coupled to the tapered sheets HW. The semiconductor device 100V may further include the contact isolation layers CIL that are disposed between the first contact nodes BLC in the vertical direction D1 and expose the outer surfaces of the first contact nodes BLC and the ohmic contact layers BLM that are disposed between the first contact nodes BLC and the second conductive lines BL and cover the outer surfaces of the first contact nodes BLC. The supporters BLS may contact directly the second conductive lines BL, the first contact nodes BLC and the protruding sheet nodes HNP.

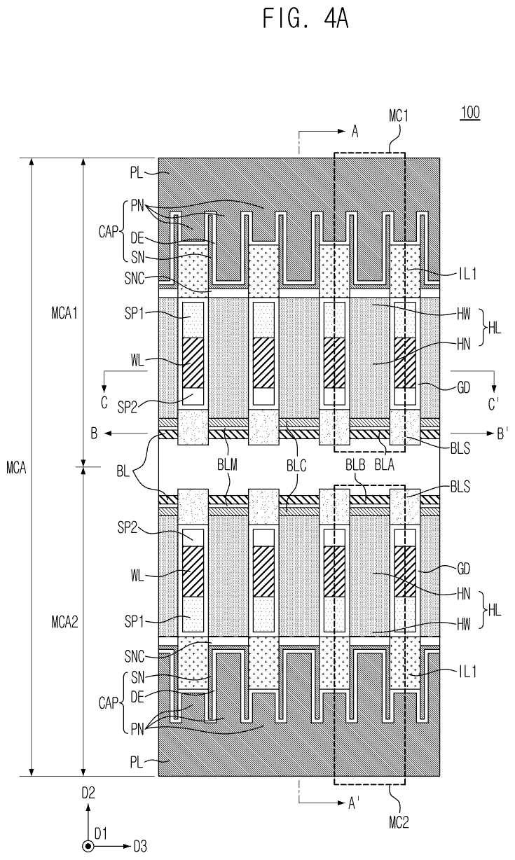

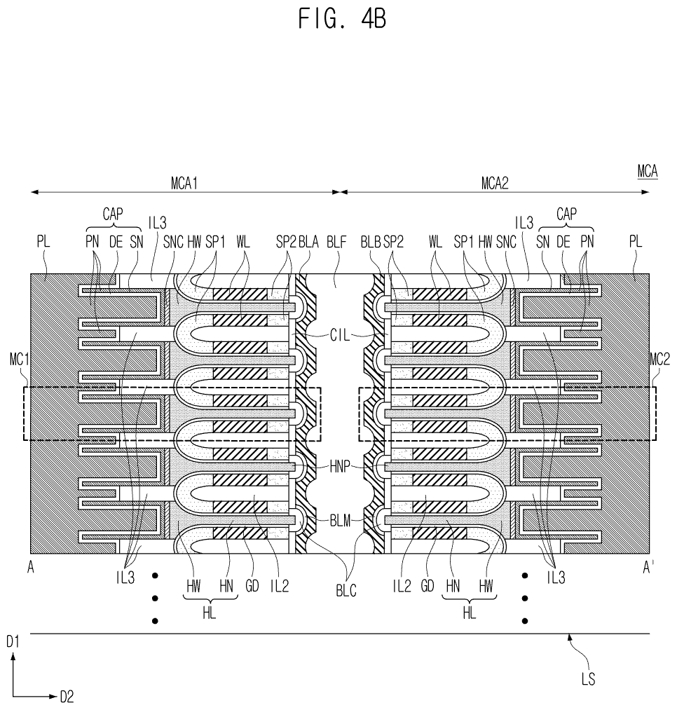

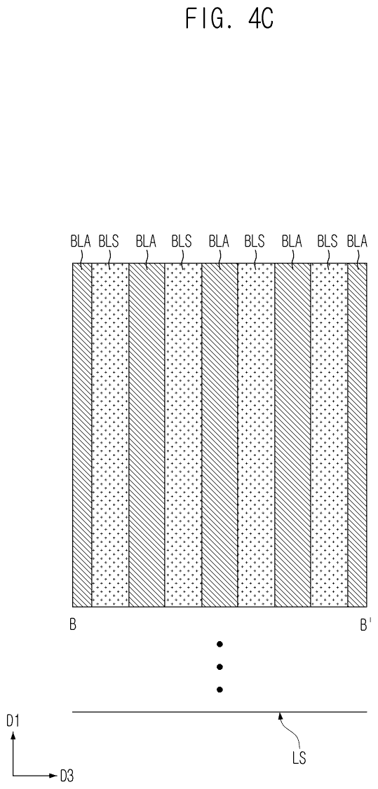

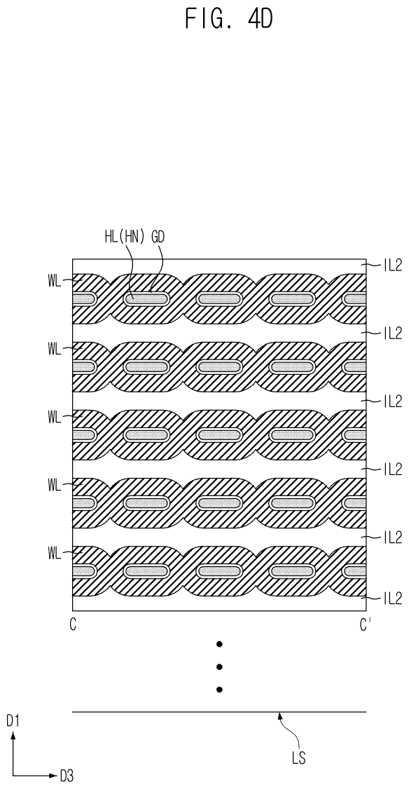

FIG. 4A is a schematic plan view of a semiconductor device 100 in accordance with an embodiment of the present disclosure. FIG. 4B is a schematic cross-sectional view of the semiconductor device 100 taken along line A-A′ illustrated in FIG. 4A. FIG. 4C is a schematic cross-sectional view of the semiconductor device 100 taken along line B-B′ illustrated in FIG. 4A. FIG. 4D is a cross-sectional view of the semiconductor device 100 taken along line C-C′ illustrated in FIG. 4A. Detailed descriptions of overlapping components are provided above with reference to FIGS. 1A to 2.

Referring to FIGS. 4A to 4D, the semiconductor device 100 may include a lower structure LS and a memory cell array MCA.

The lower structure LS may include a substrate. The lower structure LS may be a material appropriate for semiconductor processing. The lower structure LS may include a semiconductor substrate, a conductive material, a dielectric material, a semiconductive material, or a combination thereof. The lower structure LS may include silicon, monocrystalline silicon, polysilicon, amorphous silicon, silicon germanium, monocrystalline silicon germanium, polycrystalline silicon germanium, carbon-doped silicon, epitaxial silicon, a combination thereof, or multilayers thereof. The lower structure LS may also include another semiconductor material such as germanium. The lower structure LS may also include a III-V group semiconductor substrate, for example, a compound semiconductor substrate such as Gallium Arsenide (GaAs). In some embodiments, the lower structure LS may include a metal wiring structure, a dielectric structure, a conductive structure, a bonding pad structure, another memory, or a peripheral circuit portion. For example, the lower structure LS may include a structure in which the peripheral circuit portion, the metal wiring structure and the bonding pad structure are sequentially stacked. The memory cell array MCA and the peripheral circuit portion of the lower structure LS may be bonded by wafer bonding. The wafer bonding may include pad bonding, hybrid bonding, oxide-to-oxide bonding, metal-to-metal bonding, or a combination thereof.

The memory cell array MCA may include a plurality of memory cells MC1 and MC2 stacked vertically in a first direction D1. The memory cell array MCA may include a three-dimensional array of the memory cells MC1 and MC2. Each of the memory cells MC1 and MC2 may include a switching element TR and a data storage element CAP. The switching element TR may include a first conductive line WL, a nano sheet dielectric layer GD, and a nano sheet HL. The nano sheet HL may include a horizontal sheet HN and a tapered sheet HW. The horizontal sheet HN of the nano sheet HL may include a protruding sheet node HNP. A first contact node BLC may be formed between the horizontal sheet HN of the nano sheet HL and a second conductive line BL. The first contact node BLC may cover the protruding sheet node HNP. A second contact node SNC may be formed between the tapered sheet HW of the nano sheet HL and the data storage element CAP. The nano sheet HL may be surrounded by the nano sheet dielectric layer GD. The first conductive line WL may extend in a third direction D3 and may also surround a portion of the horizontal sheet HN of the nano sheet HL on the nano sheet dielectric layer GD.

The memory cells MC1 and MC2 may each have the same configuration as the memory cell MC described above with reference to FIGS. 1A to 3E. As described with reference to FIG. 1B, the nano sheets HL of the memory cells MC1 and MC2 may each include a first doped region DR, a second doped region SR, and a channel CH.

The memory cells MC1 and MC2 of the memory cell array MCA may be coupled to second conductive lines BLA and BLB. The second conductive lines BL may include a first vertical conductive line BLA and a second vertical conductive line BLB.

The memory cell array MCA may include a first sub-cell array MCA1 and a second sub-cell array MCA2. The first sub-cell array MCA1 may include a three-dimensional array of the first memory cells MC1. The second sub-cell array MCA2 may include a three-dimensional array of the second memory cells MC2. The first memory cells MC1 of the first sub-cell array MCA1 may share the second conductive line, i.e., the first vertical conductive line BLA. The second memory cells MC2 of the second sub-cell array MCA2 may share the second conductive line, i.e., the second vertical conductive line BLB. A bottom portion of the first vertical conductive line BLA may be electrically isolated from a bottom portion of the second vertical conductive line BLB.

Each of the first and second memory cells MC1 and MC2 may include the switching element TR and the data storage element CAP. The switching element TR may include the first conductive line WL and the nano sheet HL. The switching elements TR of the first and second memory cells MC1 and MC2 may be nano sheet transistors. Each of the first and second sub-cell arrays MCA1 and MCA2 may include a horizontal arrangement and a vertical arrangement of the nano sheet transistors.

The first sub-cell array MCA1 may further include a horizontal arrangement of the first vertical conductive lines BLA. The first vertical conductive lines BLA may be coupled to the horizontal sheets HN of the nano sheets HL through the first contact nodes BLC. Each of contact isolation layers CIL may be formed between the first contact nodes BLC in the first direction D1. The first memory cells MC1 may further include an ohmic contact layer BLM disposed between the first contact nodes BLC and the first vertical conductive line BLA. The ohmic contact layer BLM may include metal silicide.

The second sub-cell array MCA2 may further include a horizontal arrangement of the second vertical conductive lines BLB. The second vertical conductive lines BLB may be coupled to the horizontal sheets HN of the nano sheets HL through the first contact nodes BLC. Each of the contact isolation layers CIL may be formed between the first contact nodes BLC in the first direction D1. The second memory cells MC2 may further include an ohmic contact layer BLM disposed between the first contact nodes BLC and the second vertical conductive line BLB. The ohmic contact layer BLM may include metal silicide.

The first and second sub-cell arrays MCA1 and MCA2 may each include horizontal and vertical arrangements of the first conductive lines WL. The first and second sub-cell arrays MCA1 and MCA2 may each include horizontal and vertical arrangements of the data storage elements CAP. Each of the data storage elements CAP may include a first electrode SN, a dielectric layer DE, and a second electrode PN. The data storage element CAP may be coupled to the tapered sheet HW of the nano sheet HL through the second contact node SNC. The first contact node BLC may be doped polysilicon. The second contact node SNC may be doped polysilicon or a doped silicon epitaxial layer.

Each of the first inter-cell dielectric layers IL1 may be disposed between the data storage elements CAP adjacent to each other in the third direction D3. Each of the second inter-cell dielectric layers IL2 may be disposed between the first conductive lines WL vertically stacked in the first direction D1. Each of the third inter-cell dielectric layers IL3 may be disposed between the first electrodes SN of the data storage elements CAP vertically stacked in the first direction D1. The first to third inter-cell dielectric layers IL1, IL2 and IL3 may each include silicon oxide, silicon carbon oxide (SiCO), silicon nitride, or a combination thereof. The first inter-cell dielectric layers IL1 may be referred to also as “inter-cell isolation layers”. The second inter-cell dielectric layers IL2 may correspond to the inter-cell horizontal dielectric layers HIL illustrated in FIG. 1B. The third inter-cell dielectric layers IL3 may be inter-storage node dielectric layers. A combination of the first inter-cell dielectric layer IL1 and the third inter-cell dielectric layer IL3 may define a slot in which the first electrodes SN of the data storage elements CAP are formed.

Each of the first and second sub-cell arrays MCA1 and MCA2 may further include a first spacer SP1 and a second spacer SP2. The first spacer SP1 may be disposed between the first conductive line WL and the data storage element CAP. The second spacer SP2 may be disposed between the first conductive line WL and the first and second vertical conductive lines BLA and BLB. The first and second spacers SP1 and SP2 may vertically extend in the first direction D1 and may also horizontally extend in the third direction D3. The first spacer SP1 may horizontally extend in the third direction D3 and may also surround the tapered sheets HW at the same horizontal level. The second spacer SP2 may horizontally extend in the third direction D3 and may also surround portions of the horizontal sheets HN at the same horizontal level.

The first and second spacers SP1 and SP2 may each include silicon oxide, silicon nitride, or a combination thereof.

The first spacer SP1 may have a cup shape of covering one side of the second inter-cell dielectric layer IL2. The first spacer SP1 extending in the first direction D1 and the third direction D3 may have a frame structure surrounding a portion of the tapered sheet HW.

The second spacer SP2 may contact side surfaces of the first conductive lines WL between the second inter-cell dielectric layers IL2. The second spacer SP2 extending in the first direction D1 and the third direction D3 may have a frame structure surrounding a portion of the horizontal sheet HN.

The memory cell array MCA may include a plurality of first conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of second conductive lines BL spaced apart in the third direction D3.

An array isolation layer BLF may be disposed between the first vertical conductive line BLA and the second vertical conductive line BLB. The array isolation layer BLF may include a dielectric material. The first sub-cell array MCA1 and the second sub-cell array MCA2 may have a mirror-shaped structure with the array isolation layer BLF interposed therebetween.

The nano sheets HL of the switching elements TR horizontally disposed in the third direction D3 may share one first conductive line WL. The nano sheets HL of the switching elements TR horizontally disposed in the third direction D3 may be coupled to different second conductive lines BL. The switching elements TR stacked in the first direction D1 may share one second conductive line BL. The switching elements TR horizontally disposed in the third direction D3 may share one first conductive line WL.

The second electrodes PN of the data storage elements CAP may be coupled to a common plate PL.

The first and second vertical conductive lines BLA and BLB may be formed to be self-aligned with the second spacer SP2.

As described above, the first conductive lines WL may be isolated from one another by the second inter-cell dielectric layers IL2 in the first direction D1, and the second conductive lines BLA and BLB may be isolated from each other by supporters BLS in the third direction D3.

In an embodiment, because the first and second vertical conductive lines BLA and BLB are formed in a self-aligned manner, it is possible to increase a stack height of the memory cells MC1 and MC2 (high stack height) and carry out a high-integration process of a three-dimensional memory cell with a small cell pitch.

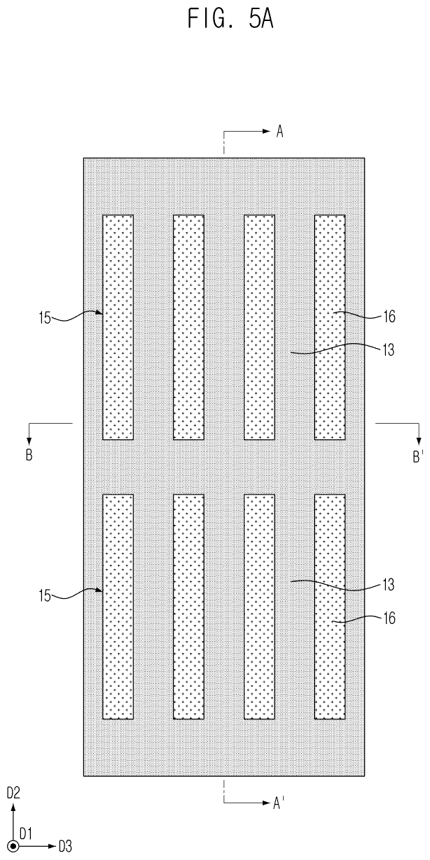

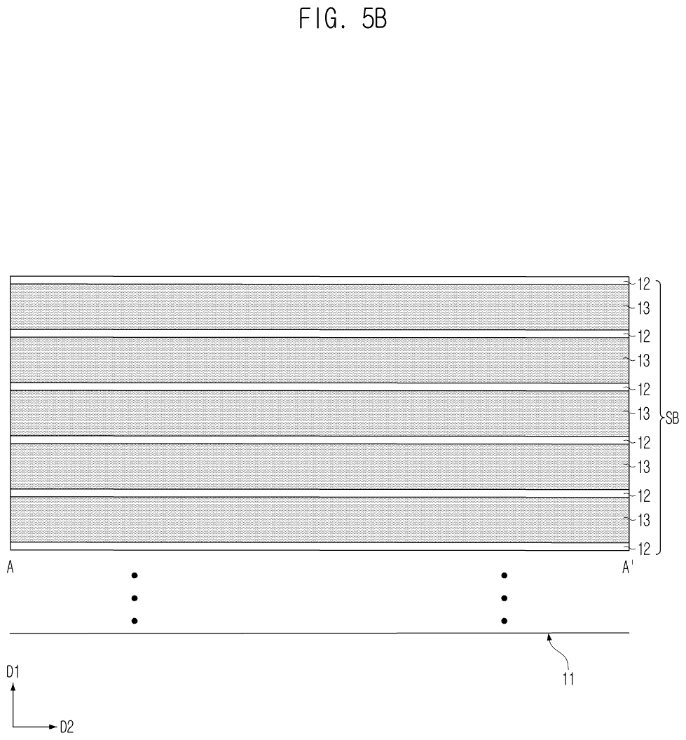

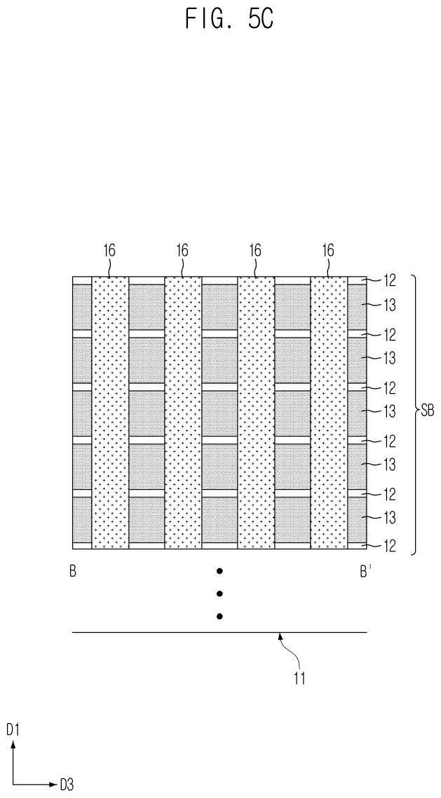

FIGS. 5A to 26B illustrate various views of a semiconductor device formed utilizing a method for fabricating the semiconductor device in accordance with an embodiment of the present disclosure.

FIG. 5A is a plan view illustrating a structure at a second mold layer level for describing a method of forming a mold stack SB. FIG. 5B is a cross-sectional view of the structure taken along line A-A′ illustrated in FIG. 5A. FIG. 5C is a cross-sectional view of the structure taken along line B-B′ illustrated in FIG. 5A.

Referring to FIGS. 5A to 5C, the mold stack SB may be formed on substrate 11 to include an alternating stack of sacrificial mold layers 12 and mold layers 13.

The substrate 11 may be a material appropriate for semiconductor processing. The substrate 11 may include a semiconductor substrate, a conductive material, a dielectric material, a semiconductive material, or a combination thereof. The substrate 11 may include silicon, monocrystalline silicon, polysilicon, amorphous silicon, silicon germanium, monocrystalline silicon germanium, polycrystalline silicon germanium, carbon-doped silicon, epitaxial silicon, a combination thereof, or multilayers thereof. The substrate 11 may also include another semiconductor material such as germanium. The substrate 11 may also include a III-V group semiconductor substrate, for example, a compound semiconductor substrate such as Gallium Arsenide (GaAs). The mold stack SB may include an alternating stack of the sacrificial mold layers 12 and the mold layers 13.

The mold stack SB may be formed by an epitaxial growth process. To form the mold stack SB, the sacrificial mold layers 12 may be alternately stacked with the mold layers 13, and the sacrificial mold layers 12 and the mold layers 13 may be epitaxially grown.

The sacrificial mold layers 12 and the mold layers 13 may be different semiconductive materials. For example, the sacrificial mold layers 12 may each include silicon germanium or monocrystalline silicon germanium. Also, as an example, the mold layers 13 may each include monocrystalline silicon. The sacrificial mold layers 12 and the mold layers 13 may be formed by the epitaxial growth process. A lowermost sacrificial mold layer 12 may serve as a seed layer during the epitaxial growth process. Each of the sacrificial mold layers 12 may be thinner than each of the mold layers 13. The sacrificial mold layers 12 may include first epitaxially grown layers, and the mold layers 13 may include second epitaxially grown layers.

In an embodiment, a plurality of monocrystalline silicon germanium layers may be alternately stacked with a plurality of monocrystalline silicon layers in the mold stack SB. For example, the sacrificial mold layers 12 may be the monocrystalline silicon germanium layers, and the mold layers 13 may be the monocrystalline silicon layers. A stack of a monocrystalline silicon germanium layer and a monocrystalline silicon layer (a SiGe/Si stack) may be stacked multiple times. The sacrificial mold layers 12 may also be referred to as “sacrificial layers”, and the mold layers 13 may be referred to also as “nano sheet target layers”.

The mold stack SB may be referred to as a “vertical stack”. The mold stack SB may be formed by alternately stacking a plurality of sacrificial layers and a plurality of nano sheet target layers. The sacrificial layers may be monocrystalline silicon germanium layers, and the nano sheet target layers may be monocrystalline silicon layers.

A thickness ratio of the sacrificial mold layers 12 and a thickness ratio of the mold layers 13 in the mold stack SB may be variously modified. For example, the thickness of each of the sacrificial mold layers 12 may be 5 to 20 nm, and the thickness of each of the mold layers 13 may be 50 to 80 nm. Furthermore, the number (or quantity) of the sacrificial mold layers 12 and the number (or quantity) of the mold layers 13 in the mold stack SB may be variously modified.

Subsequently, a plurality of inter-cell isolation openings 15 may be formed by etching portions of the mold stack SB. The inter-cell isolation openings 15 may be openings for memory cell isolation. From the perspective of a top view, a cross-section of each of the inter-cell isolation openings 15 may have a rectangular shape. However, the embodiments are not limited to this configuration only, and in some embodiments, the cross-section of each of the inter-cell isolation openings 15 may have a circular shape or an oval shape. In some embodiments, the inter-cell isolation openings 15 may be referred to also as “inter-cell isolation trenches”. The inter-cell isolation openings 15 may vertically extend in a first direction D1 and extend lengthwise in a second direction D2. The inter-cell isolation openings 15 may be disposed at a predetermined interval in a third direction D3. Bottom surfaces of the inter-cell isolation openings 15 may extend inside of the substrate 11.

Continuously, sacrificial isolation layers 16 may be formed to fill the inter-cell isolation openings 15. The sacrificial isolation layers 16 may include the same material. The sacrificial isolation layers 16 may each be formed of a dielectric material. The sacrificial isolation layers 16 may have an etch selectivity with respect to the mold stack SB. For example, the sacrificial isolation layers 16 may each include silicon oxide, silicon nitride, silicon carbon oxide, silicon carbon nitride, or a combination thereof. Forming the sacrificial isolation layers 16 may include forming inter-cell isolation materials to fill the inter-cell isolation openings 15 and planarizing the inter-cell isolation materials.

The sacrificial isolation layers 16 may vertically extend in the first direction D1 and extend lengthwise in the second direction D2. The sacrificial isolation layers 16 may be disposed at a predetermined interval in the third direction D3. The sacrificial isolation layers 16 may pass through the mold stack SB in the first direction D1.

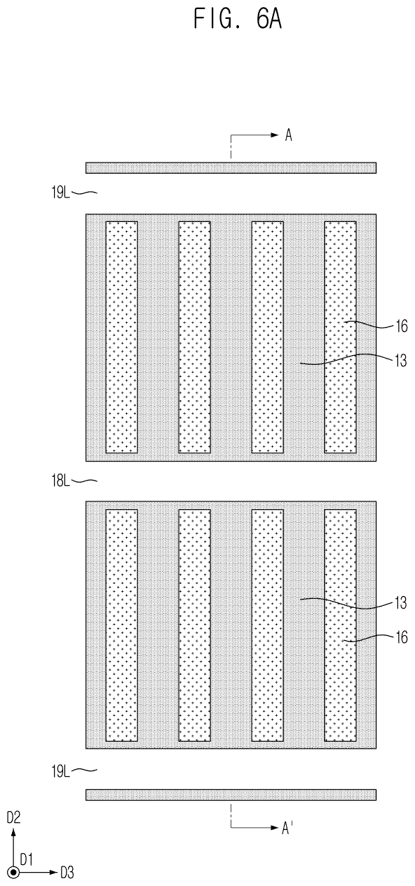

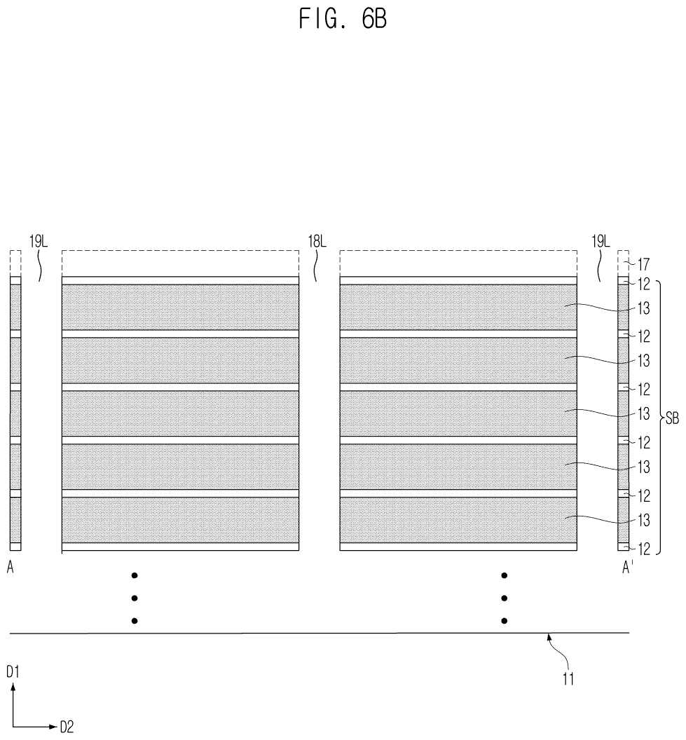

FIG. 6A is a plan view illustrating the structure at a mold layer level for describing a method of forming sacrificial linear openings 18L and 19L. FIG. 6B is a cross-sectional view of the structure taken along line A-A′ illustrated in FIG. 6A.

Referring to FIGS. 6A and 6B, portions of the mold stack SB where the sacrificial isolation layers 16 are not formed may be etched to form a plurality of sacrificial linear openings 18L and 19L. The sacrificial linear openings may include a first sacrificial linear opening 18L and a second sacrificial linear opening 19L. The mold stack SB may be etched using a hard mask layer 17, to form the sacrificial linear openings 18L and 19L. From the perspective of a top view, the first and second sacrificial linear openings 18L and 19L may be line-shaped openings extending in the third direction D3. The first and second sacrificial linear openings 18L and 19L may vertically extend in the first direction D1. The sacrificial isolation layers 16 may be disposed between the first sacrificial linear opening 18L and the second sacrificial linear opening 19L in the second direction D2. From the perspective of a top view, cross sections of the first and second sacrificial linear openings 18L and 19L may each have a rectangular shape. In some embodiments, the cross sections of the first and second sacrificial linear openings 18L and 19L may each have a circular shape or an oval shape. The first and second sacrificial linear openings 18L and 19L may each have a width in the second direction D2 which is less than a width in the third direction D3. The first and second sacrificial linear openings 18L and 19L may be referred to also as “sacrificial linear trenches”. The sacrificial isolation layers 16 may not contact the first and second sacrificial linear openings 18L and 19L.

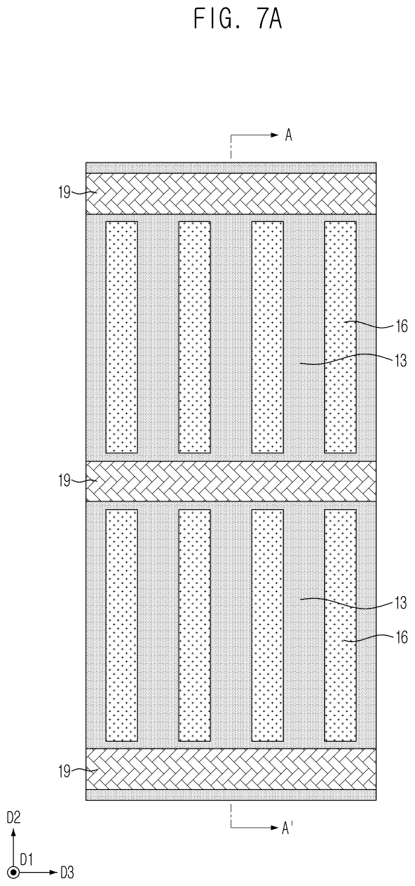

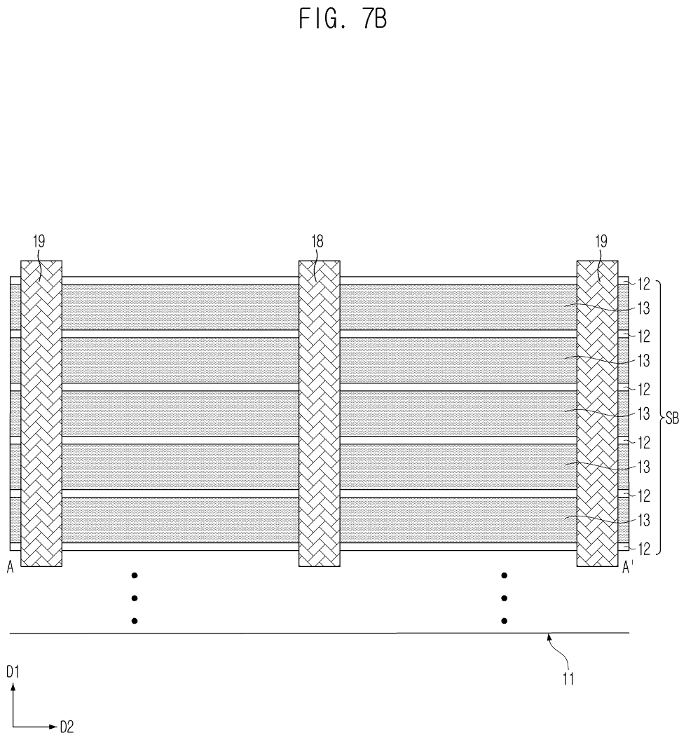

FIG. 7A is a plan view illustrating the structure at the mold layer level for describing a method of forming linear sacrificial layers 18 and 19. FIG. 7B is a cross-sectional view of the structure taken along line A-A′ illustrated in FIG. 7A.

Referring to FIGS. 7A and 7B, the linear sacrificial layers 18 and 19 may be formed to fill the first and second sacrificial linear openings 18L and 19L. The linear sacrificial layers may include a first linear sacrificial layer 18 and a second linear sacrificial layer 19. From the perspective of a top view, the first and second linear sacrificial layers 18 and 19 may have line shapes extending in the third direction D3. The first and second linear sacrificial layers 18 and 19 may each vertically extend in the first direction D1. The sacrificial isolation layers 16 may be disposed between the first linear sacrificial layer 18 and the second linear sacrificial layer 19 in the second direction D2. From the perspective of a top view, cross sections of the first and second linear sacrificial layers 18 and 19 may each have a rectangular shape. In some embodiments, the cross-sections of the first and second linear sacrificial layers 18 and 19 may each have a circular shape or an oval shape. The first and second linear sacrificial layers 18 and 19 may include the same material. The first and second linear sacrificial layers 18 and 19 may each be formed of a dielectric material. For example, the first and second linear sacrificial layers 18 and 19 may each include silicon oxide, silicon nitride, silicon carbon oxide, silicon carbon nitride, or a combination thereof. The sacrificial isolation layers 16 may not contact the first and second linear sacrificial layers 18 and 19.

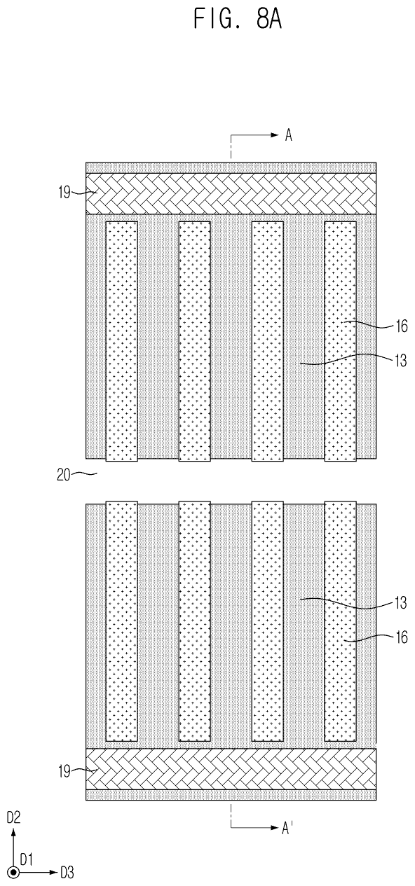

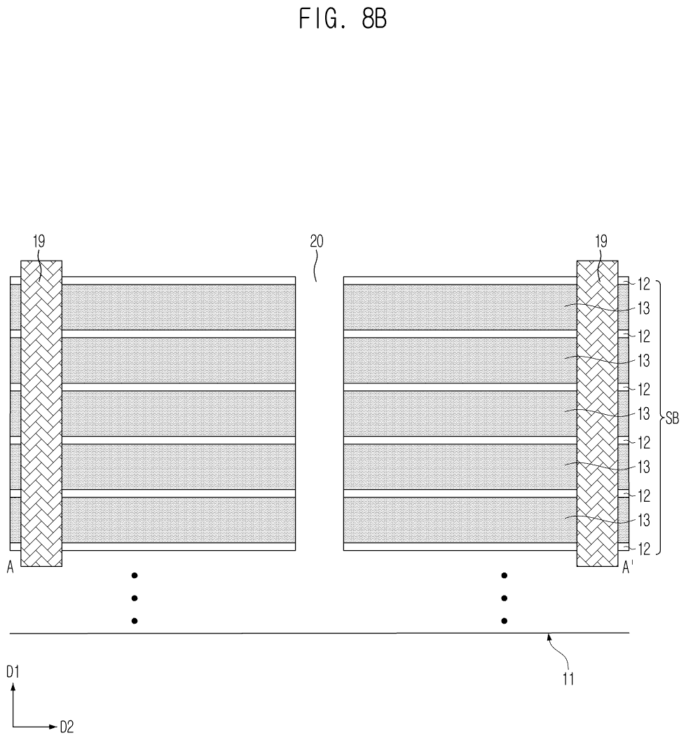

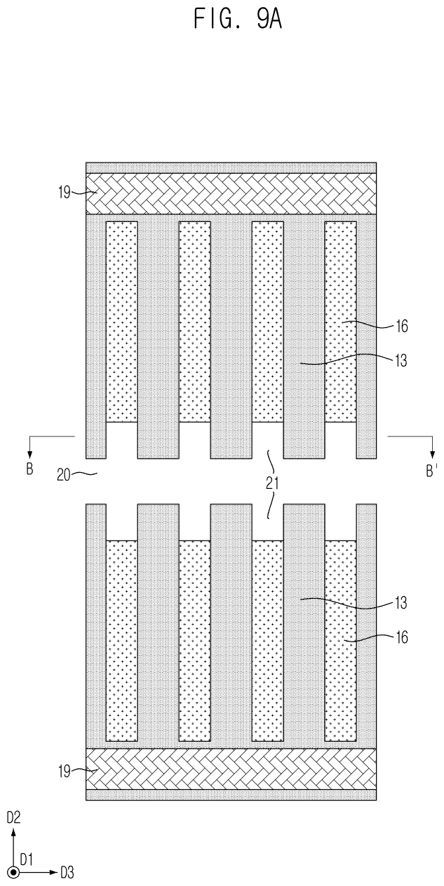

FIG. 8A is a plan view illustrating the structure at the mold layer level for describing the recessing of the sacrificial mold layers 12. FIG. 8B is a cross-sectional view of the structure taken along line A-A′ illustrated in FIG. 8A.

Referring to FIGS. 8A and 8B, among the first linear sacrificial layer 18 and the second linear sacrificial layer 19, the first linear sacrificial layer 18 may be selectively removed. A hard mask layer (not illustrated) may be used as an etch barrier to remove the first linear sacrificial layer 18. After the first linear sacrificial layer 18 is removed, the sacrificial mold layers 12 and the mold layers 13 may be partially trimmed to form a first linear opening 20.

From the perspective of a top view, the first linear opening 20 may be disposed horizontally spaced apart from the second linear sacrificial layer 19 in the second direction D2. As illustrated in FIG. 8A each first linear opening 20 may be positioned between two adjacent second sacrificial layers 19. More specifically, each first linear opening 20 may be positioned at a mid-distance between two adjacent second linear sacrificial layers 19. Each first linear opening 20 may be located equidistantly between two neighboring second linear sacrificial layers 19.

The first linear opening 20 may have the same size as or may be larger than the first sacrificial linear opening 18L which was described with reference to FIG. 6A. A bottom surface of the first linear opening 20 may be at the same level as a bottom surface of the first sacrificial linear opening 18L. The bottom surface of the first linear opening 20 may be at the same level as the bottom surfaces of the sacrificial isolation layers 16.

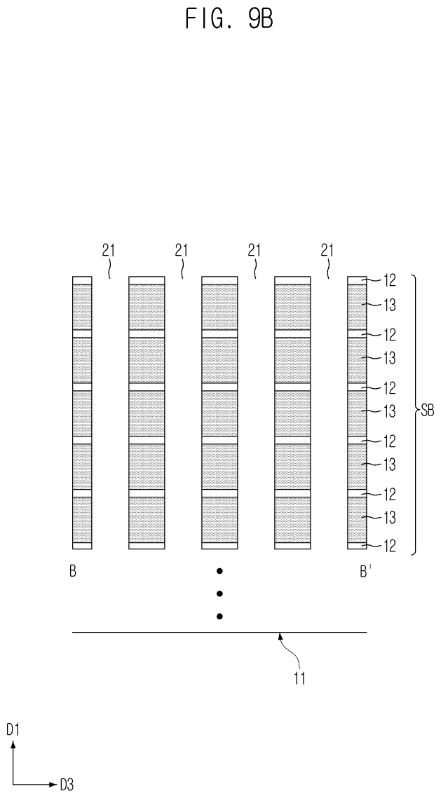

FIG. 9A is a plan view illustrating the structure at a horizontal sheet level for describing a method of forming supporter openings 21. FIG. 9B is a cross-sectional view of the structure taken along line B-B′ illustrated in FIG. 9A.

Referring to FIGS. 9A and 9B, portions of the sacrificial isolation layers 16 may be horizontally recessed in the second direction D2 through the first linear opening 20. Accordingly, a plurality of supporter openings 21 may be formed. The supporter openings 21 may vertically extend in the first direction D1 and may also be disposed between the mold layers 13.

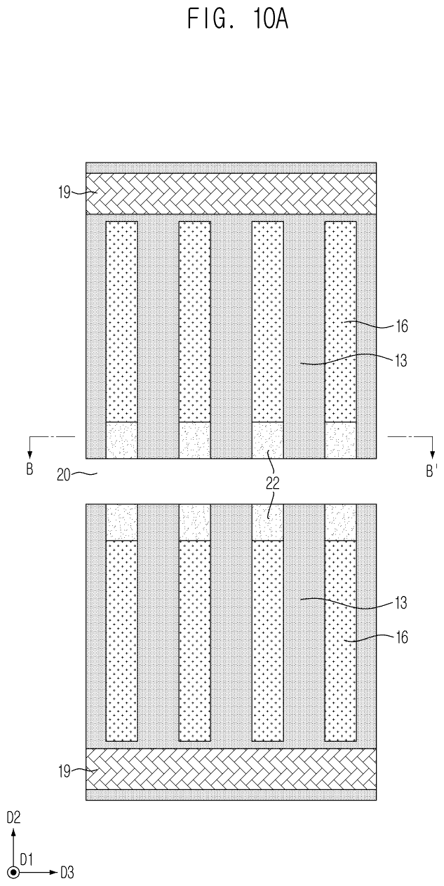

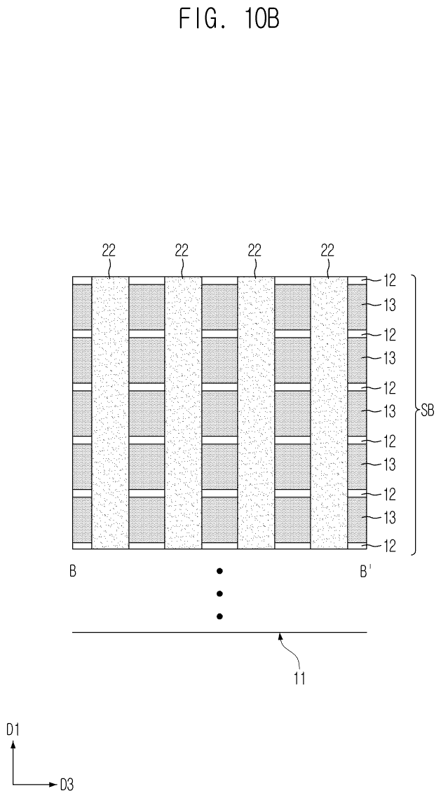

FIG. 10A is a plan view illustrating the structure at the horizontal sheet level for describing a method of forming supporters 22. FIG. 10B is a cross-sectional view of the structure taken along line B-B′ illustrated in FIG. 10A.

Referring to FIGS. 10A and 10B, the supporters 22 may be formed to fill the supporter openings 21. The supporters 22 may be formed by depositing a dielectric material in the supporter openings 21 and etching any excess over the top surface of the supporter openings 21. The supporters 22 may each include silicon oxide, silicon nitride, or a combination thereof. The supporters 22 and the sacrificial isolation layers 16 may include different materials. The supporters 22 may be silicon nitride, and the sacrificial isolation layers 16 may be silicon oxide. The supporters 22 may vertically extend in the first direction D1 and may also be disposed between the mold layers 13.

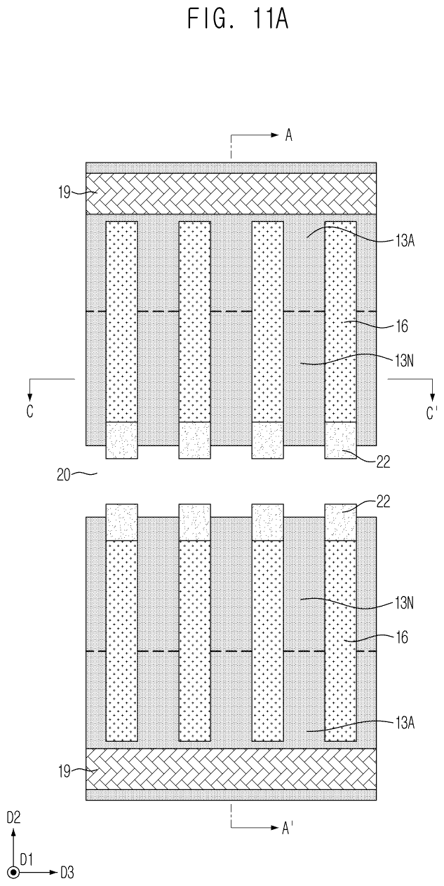

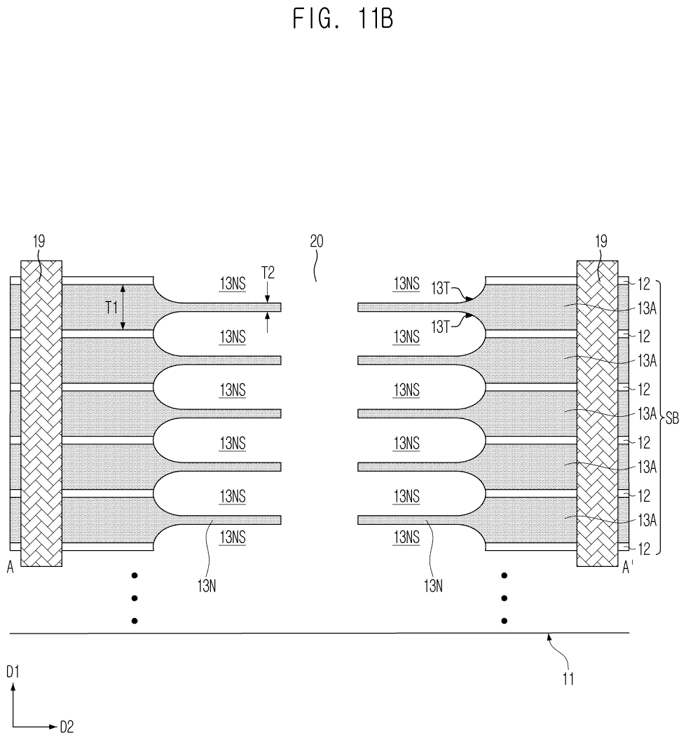

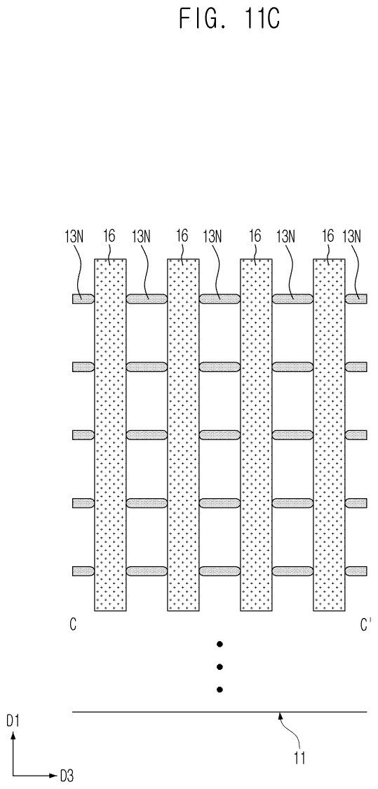

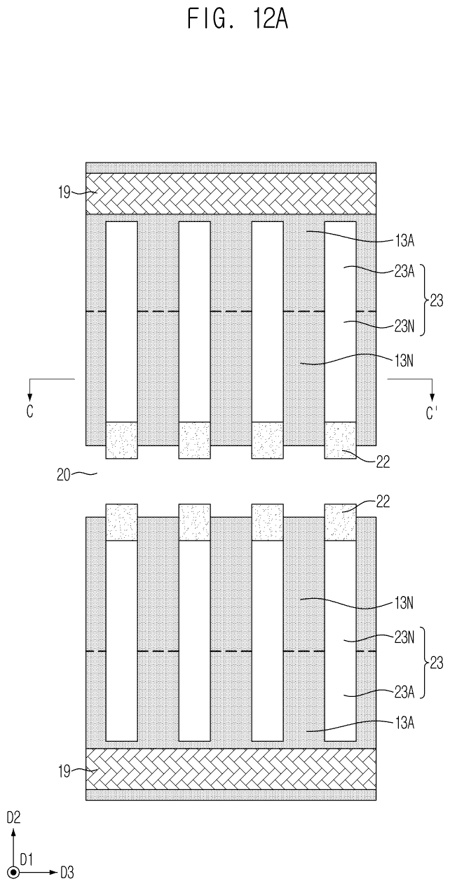

FIG. 11A is a plan view illustrating the structure at the horizontal sheet level for describing a method of forming horizontal sheets 13N. FIG. 11B is a cross-sectional view of the structure taken along line A-A′ illustrated in FIG. 11A. FIG. 11C is a cross-sectional view of the structure taken along line C-C′ illustrated in FIG. 11A.

Referring to FIGS. 11A to 11C, the sacrificial mold layers 12 may be partially recessed. The partial recessing process of the sacrificial mold layers 12 may be referred to as a cutting process of the sacrificial mold layers 12.

A difference in etch selectivity between the sacrificial mold layers 12 and the mold layers 13 may be used to selectively recess the sacrificial mold layers 12. The sacrificial mold layers 12 may be removed using a wet etch process or a dry etch process. For example, when the sacrificial mold layers 12 include silicon germanium layers, and the mold layers 13 include monocrystalline silicon layers, the silicon germanium layers may be etched using an etchant or etch gas having a selectivity with respect to the monocrystalline silicon layers.

Subsequently, a portion (a first portion) of each of the mold layers 13 may be recessed. The wet etch process or dry etch process may be used to recess the mold layers 13.

Pre-nano sheet layers may be formed by the partial recessing of the mold layers 13. The pre-nano sheet layers may include body sheets 13A and horizontal sheets 13N. The horizontal sheets 13N may horizontally extend from the body sheets 13A. A tapered profile 13T may be defined between the horizontal sheets 13N and the body sheets 13A. The horizontal sheets 13N and the body sheets 13A may have an integral structure that is continuous in the second direction D2.

Each of the body sheets 13A may maintain an original thickness T1, while each of the horizontal sheets 13N may have a thickness T2 less than the original thickness T1. The tapered profile 13T may have a thickness that gradually increases from the horizontal sheets 13N toward the body sheets 13A.

A horizontal length of the body sheet 13A in the second direction D2 may be equal to or different from a horizontal length of the horizontal sheet 13N in the second direction D2. Each of the horizontal sheets 13N may be disposed between the sacrificial isolation layers 16 in the third direction D3. In addition, each of the body sheets 13A may be disposed between the sacrificial isolation layers 16 in the third direction D3.

A recessing process for forming the horizontal sheets 13N may be referred to as a “thinning process” or “trimming process” of the mold layers 13. To form the horizontal sheets 13N, upper surfaces, lower surfaces and side surfaces of the mold layers 13 may be recessed. The horizontal sheets 13N may include a monocrystalline silicon layer. The recessing process for forming the horizontal sheets 13N may use an etchant having a selectivity with respect to the sacrificial mold layers 13 and the sacrificial isolation layers 16.

The horizontal sheets 13N may be formed by the partial recessing process for the mold layers 13 as described above. Each of the inter-horizontal sheet recesses 13NS may be formed between the horizontal sheets 13N in the first direction D1. Upper and lower surfaces of the horizontal sheets 13N may each include a flat surface. The tapered profile 13T disposed between the body sheets 13A and the horizontal sheets 13N may have a curved shape or an angled shape. Each of the sacrificial mold layers 12 may be disposed between the body sheets 13A that are vertically stacked. Each of the inter-horizontal sheet recesses 13NS may be formed between the sacrificial isolation layers 16 in the third direction D3.

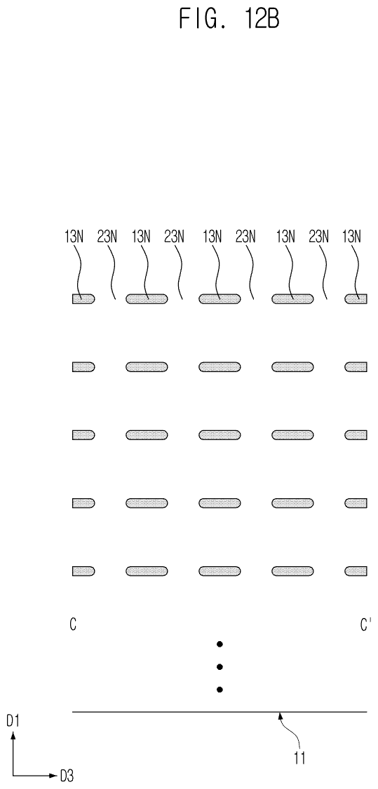

FIG. 12A is a plan view illustrating the structure at the horizontal sheet level for describing a method of forming inter-sheet openings 23. FIG. 12B is a cross-sectional view of the structure taken along line C-C′ illustrated in FIG. 12A.

Referring to FIGS. 12A and 12B, the sacrificial isolation layers 16 may be selectively removed in the second direction D2 to form the inter-sheet openings 23. Each of the inter-sheet openings 23 may be formed between the horizontal sheets 13N in the third direction D3. The inter-sheet openings 23 may vertically extend in the first direction D1.

Each of the inter-sheet openings 23 may include an inter-horizontal sheet opening 23N and an inter-body sheet opening 23A. The inter-horizontal sheet opening 23N and the inter-body sheet opening 23A may have an integral structure. The inter-horizontal sheet opening 23N may be formed between the horizontal sheets 13N in the third direction D3, and the inter-body sheet opening 23A may be formed between the body sheets 13A in the third direction D3.

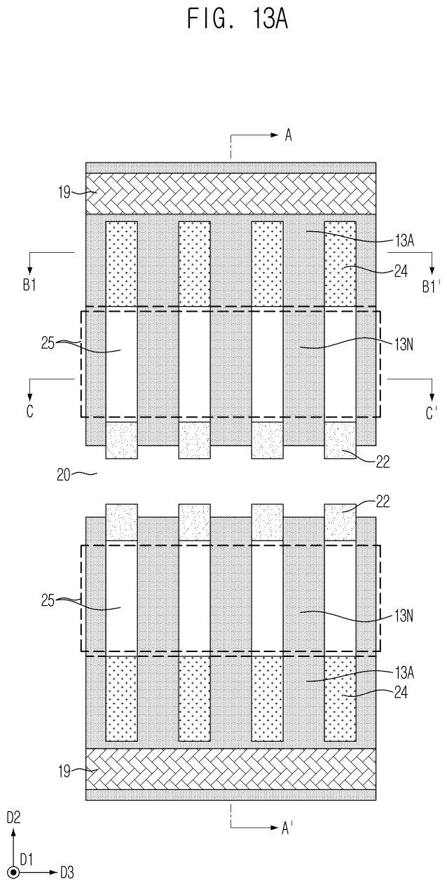

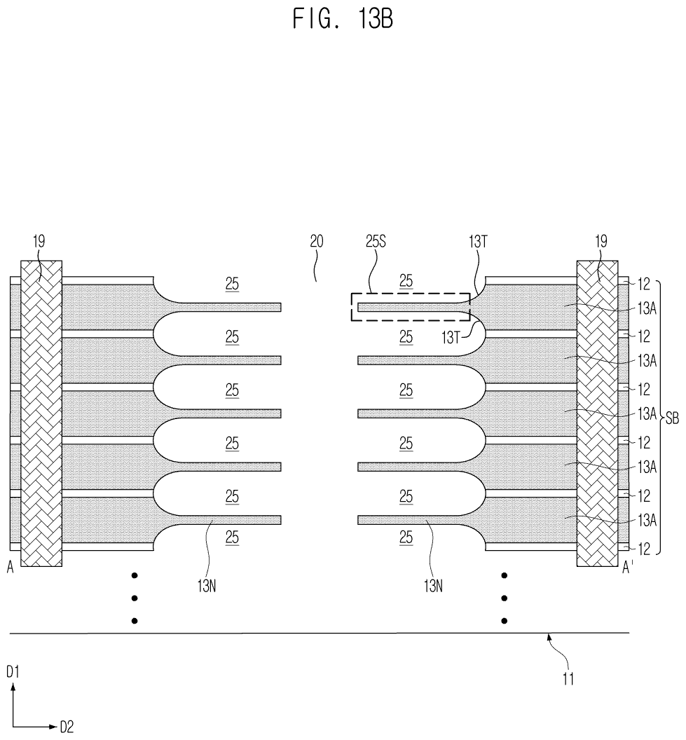

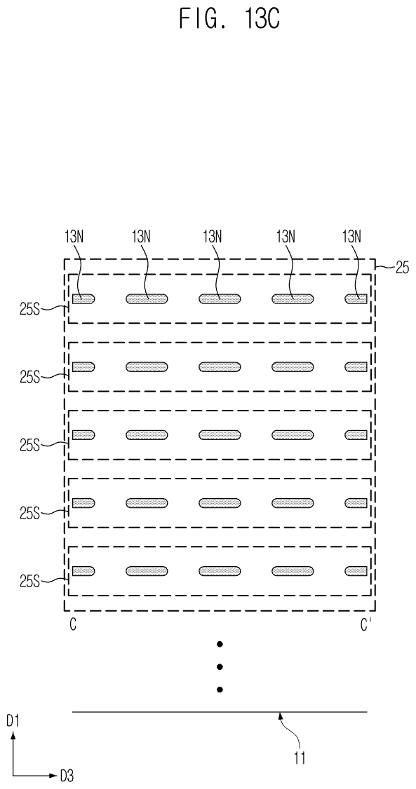

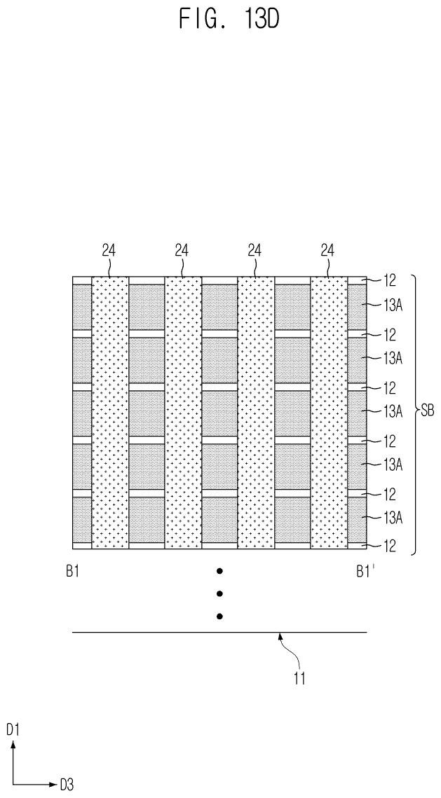

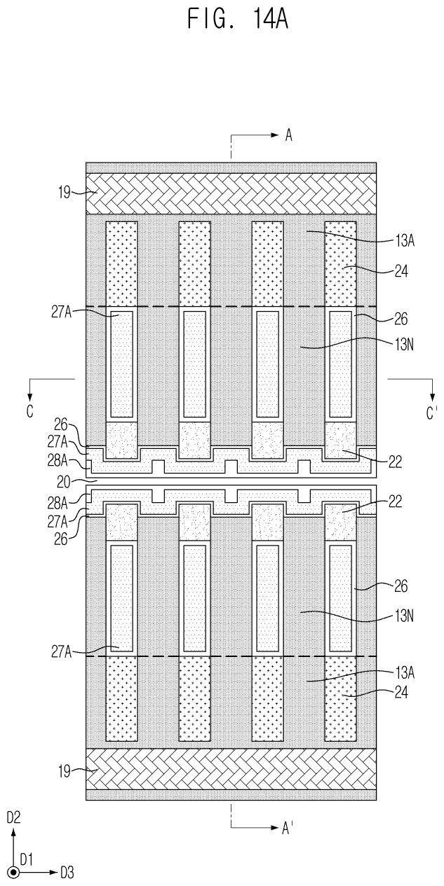

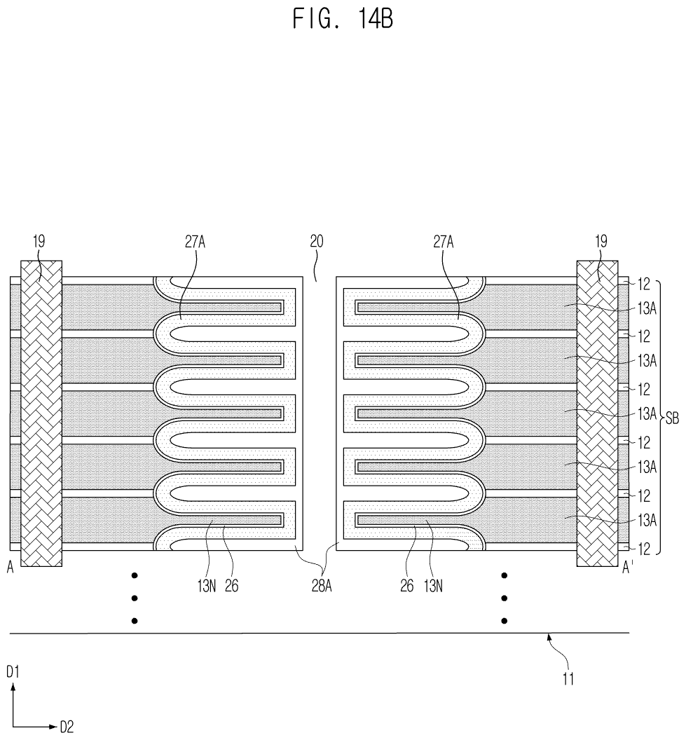

FIG. 13A is a plan view illustrating the structure at the horizontal sheet level for describing a method of forming first inter-cell dielectric layers 24. FIG. 13B is a cross-sectional view of the structure taken along line A-A′ illustrated in FIG. 13A. FIG. 13C is a cross-sectional view of the structure taken along line C-C′ illustrated in FIG. 13A. FIG. 13D is a cross-sectional view of the structure taken along line D-D′ illustrated in FIG. 13A.

Referring to FIGS. 13A to 13D, the first inter-cell dielectric layers 24 may be formed to fill the inter-body sheet openings 23A. Forming the first inter-cell dielectric layers 24 may include forming (e.g., by deposition) a dielectric material to fill the inter-sheet openings 23 and horizontally recessing the dielectric material to form the first inter-cell dielectric layers 24 filling the inter-body sheet openings 23A. The first inter-cell dielectric layers 24 may each include silicon oxide, silicon nitride, or a combination thereof. The first inter-cell dielectric layers 24 may not be formed in the inter-horizontal sheet recesses 13NS and the inter-horizontal sheet openings 23N.

The inter-horizontal sheet recesses 13NS and inter-horizontal sheet openings 23N together facilitate the complete opening of all horizontal sheets 13N. In effect, their combination forms a horizontal sheet all-open recess 25, which comprises multiple surrounding recesses 25S. These surrounding recesses 25S ensure exposure of all horizontal sheets 13N at a uniform horizontal level along the third direction D3. Specifically, any surrounding recess 25S extending along the third direction D3 can encompass all surfaces of the horizontal sheets 13N positioned at the same horizontal level.

Referring to FIGS. 12A to 13D, the sacrificial isolation layers 16 may be replaced with the first inter-cell dielectric layers 24. After a replacement process of the first inter-cell dielectric layers 24, the horizontal sheet all-open recess 25 may be formed between the first inter-cell dielectric layers 24 and the supporters 22 to expose the horizontal sheets 13N.

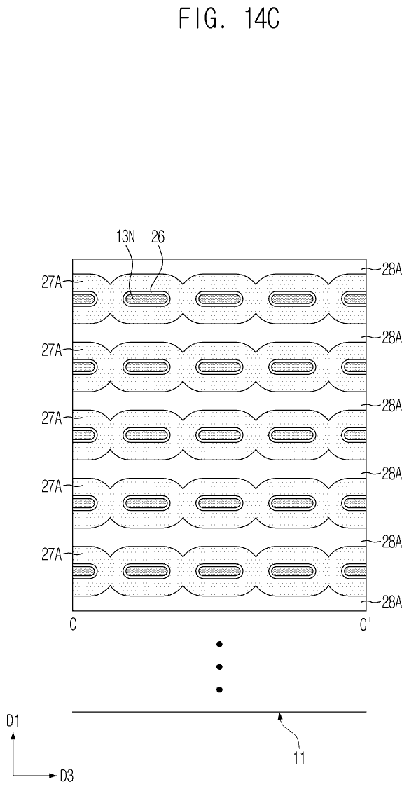

FIG. 14A is a plan view illustrating the structure at the horizontal sheet level for describing a method of forming a first spacer layer 27A. FIG. 14B is a cross-sectional view of the structure taken along line A-A′ illustrated in FIG. 14A. FIG. 14C is a cross-sectional view of the structure taken along line C-C′ illustrated in FIG. 14A.

Referring to FIGS. 14A to 14C, a nano sheet dielectric layer 26 may be formed onto the exposed surface portions of the horizontal sheets 13N. The nano sheet dielectric layer 26 may be referred to also as a “gate dielectric layer”.

The nano sheet dielectric layer 26 may be formed by oxidizing the surfaces of the horizontal sheets 13N. In some embodiments, the nano sheet dielectric layer 26 may be formed by deposition and oxidation processes of silicon oxide. The nano sheet dielectric layer 26 may include silicon oxide, silicon nitride, metal oxide, metal oxynitride, metal silicate, a high-k material, a ferroelectric material, an anti-ferroelectric material, or a combination thereof. The nano sheet dielectric layer 26 may include silicon dioxide (SiO₂), silicon nitride (Si₃N₄), hafnium dioxide (HfO₂), aluminum oxide (Al₂O₃), zirconium dioxide (ZrO₂), aluminum oxynitride (AlON), hafnium oxynitride (HfON), hafnium silicate (HfSiO), hafnium silicon oxynitride (HfSiON), or a combination thereof. The nano sheet dielectric layer 26 may be formed on all surfaces of the horizontal sheets 13N.

Subsequently, the first spacer layer 27A may be formed in the surrounding recesses 25S. The first spacer layer 27A may include, for example, silicon nitride. The first spacer layer 27A may be used as a sacrificial material to define a space where subsequent first conductive lines are to be formed. The first spacer layer 27A may include a single-layer structure or a multi-layer structure. The first spacer layer 27A may include silicon oxide, silicon nitride, or a combination thereof. The first spacer layer 27A may fill all of the other spaces of the inter-horizontal sheet openings 23N on the nano sheet dielectric layer 26.

The first spacer layer 27A may surround and cover the horizontal sheets 13N on the nano sheet dielectric layer 26. The first spacer layer 27A may be thicker than the nano sheet dielectric layer 26.

A second inter-cell dielectric layer 28A may be formed on the first spacer layer 27A. The second inter-cell dielectric layer 28A may fill the surrounding recesses 25S on the first spacer layer 27A.

Referring to FIGS. 11A to 14C, the inter-horizontal sheet recesses (reference numeral “13NS” of FIG. 11B) may be filled with the nano sheet dielectric layer 26, the first spacer layer 27A and the second inter-cell dielectric layer 28A. The second inter-cell dielectric layer 28A may include silicon oxide. The first spacer layer 27A and the second inter-cell dielectric layer 28A may not fill the first linear opening 20.

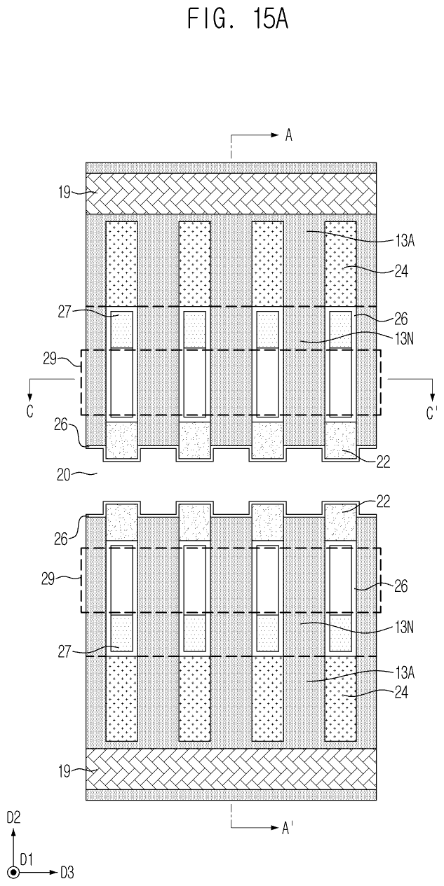

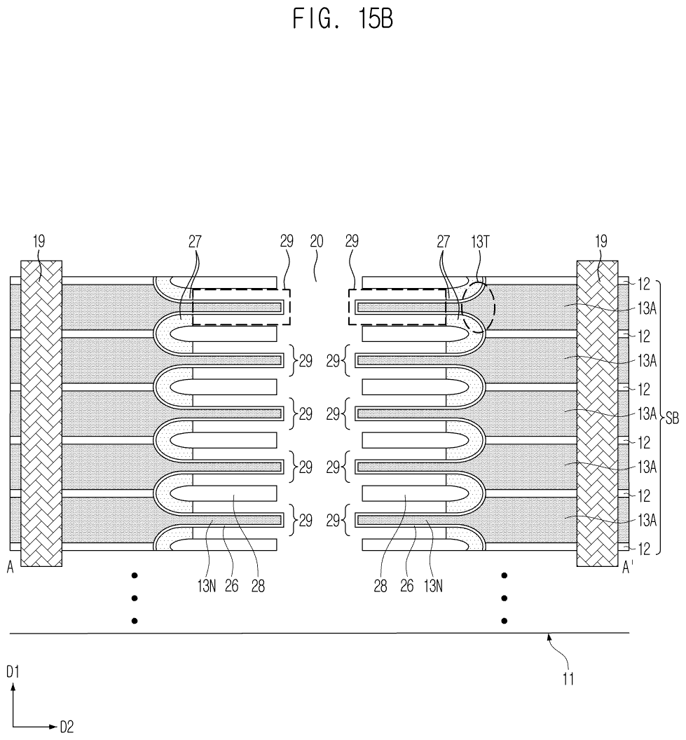

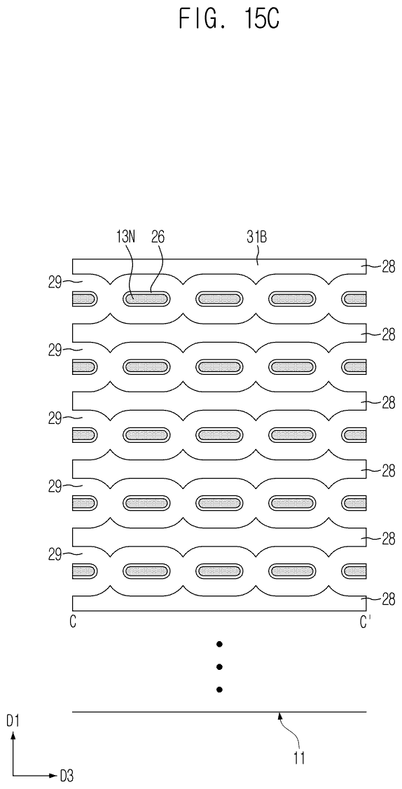

FIG. 15A is a plan view illustrating the structure for describing a method of forming first spacers 27. FIG. 15B is a cross-sectional view of the structure taken along line B-B′ illustrated in FIG. 15A. FIG. 15C is a cross-sectional view of the structure taken along line C-C′ illustrated in FIG. 15A.

Referring to FIGS. 15A to 15B, a recessing process may be performed on the first spacer layer 27A to form first spacers 27. The recessing process may include a side recessing process or a horizontal recessing process. The first spacers 27 may be referred to also as “recessed spacers” or “horizontal recessed spacers”.

The recessing process for the first spacer layer 27A may include, for example, an oxide recessing process, a nitride recessing process, or a combination thereof. For example, when the first spacer layer 27A is silicon nitride, the first spacers 27 may be formed by side recessing of nitride.

The first spacers 27 may vertically extend in the first direction D1 and may also surround boundary portions of the horizontal sheets 13N and the body sheets 13A, i.e., the tapered profiles 13T. In addition, the first spacers 27 may horizontally extend in the third direction D3 and may also surround the tapered profiles 13T disposed between the horizontal sheets 13N and the body sheets 13A.

As the first spacers 27 are formed, linear surrounding recesses 29 surrounding the horizontal sheets 13N may be formed on the nano sheet dielectric layer 26. Each of the second inter-cell dielectric layers 28 may be disposed between the linear surrounding recesses 29 that are vertically disposed. Each of the first spacers 27 may have a cup shape covering one side of each of the second inter-cell dielectric layers 28. Each of the first spacers 27 extending in the first direction D1 and the third direction D3 may have a frame structure surrounding each of the tapered profiles 13T.

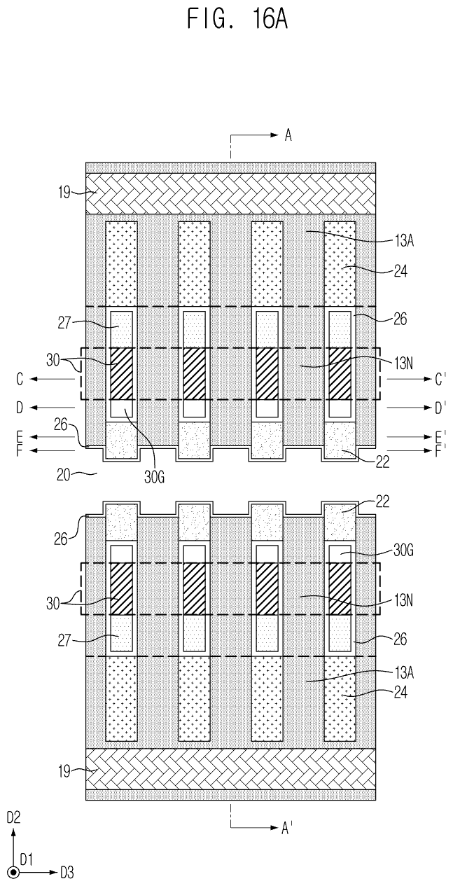

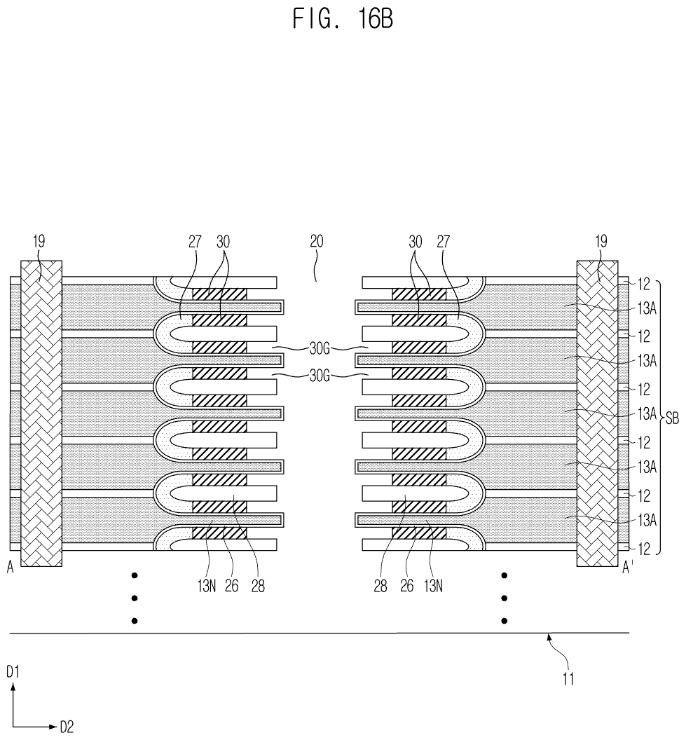

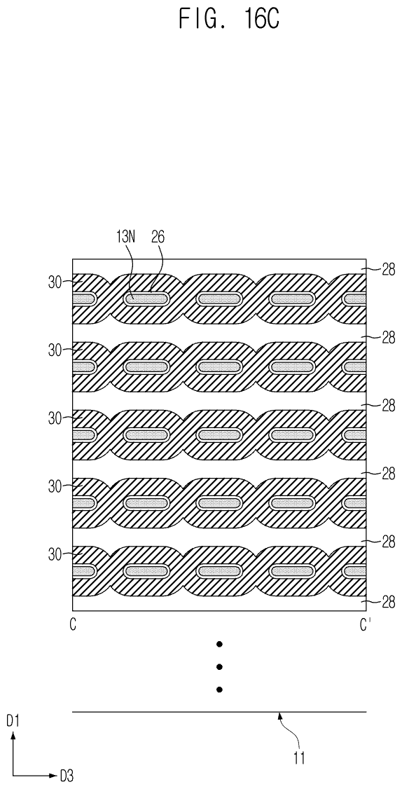

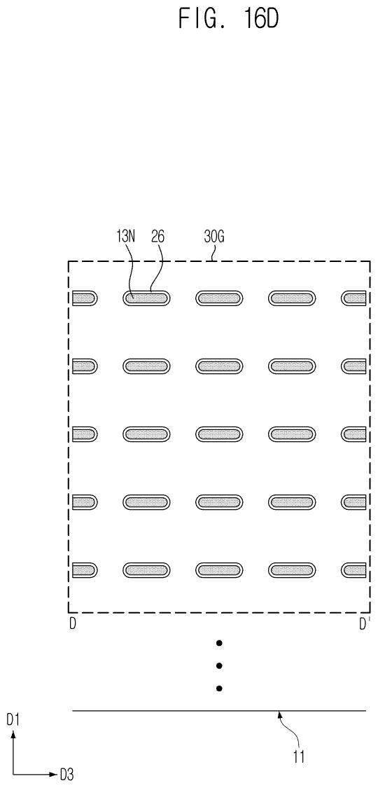

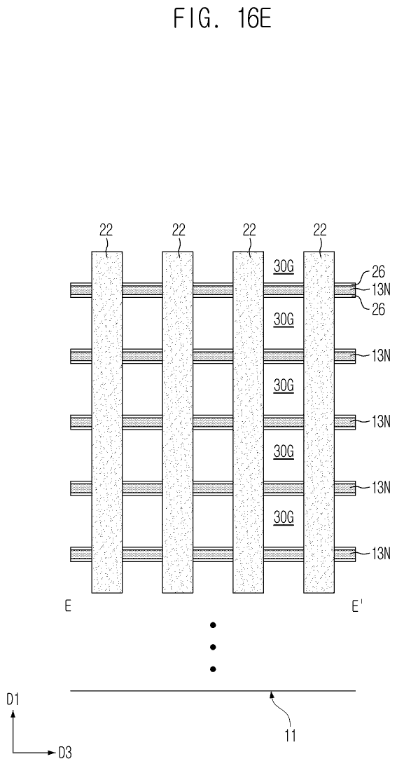

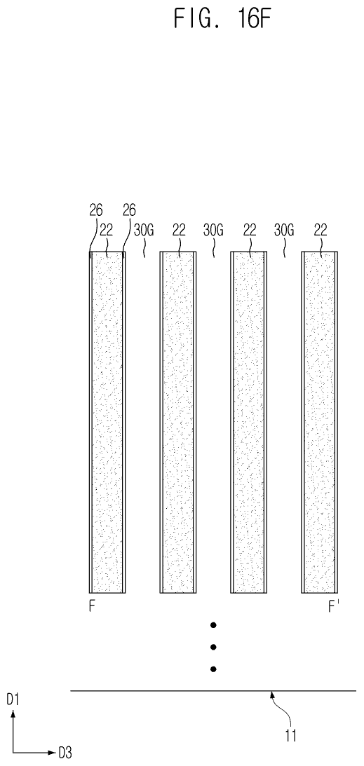

FIG. 16A is a plan view illustrating the structure at the horizontal sheet level for describing a method of forming first conductive lines 30. FIG. 16B is a cross-sectional view of the structure taken along line A-A′ illustrated in FIG. 16A. FIG. 16C is a cross-sectional view of the structure taken along line C-C′ illustrated in FIG. 16A. FIG. 16D is a cross-sectional view of the structure taken along line D-D′ illustrated in FIG. 16A. FIG. 16E is a cross-sectional view of the structure taken along line E-E′ illustrated in FIG. 16A. FIG. 16F is a cross-sectional view of the structure taken along line F-F′ illustrated in FIG. 16A.

Referring to FIGS. 16A to 16F, the first conductive lines 30 may be formed to fill the linear surrounding recesses 29. The first conductive lines 30 may horizontally extend in the third direction D3.

Forming the first conductive lines 30 may include depositing a conductive material that fills the linear surrounding recesses 29 on the nano sheet dielectric layer 26 and performing a horizontal recessing process on the conductive material. The first conductive lines 30 may each include a metal-based material, a semiconductive material, or a combination thereof. The first conductive lines 30 may each include molybdenum, molybdenum nitride, ruthenium, titanium nitride, tungsten, polysilicon, or a combination thereof. For example, the first conductive lines 30 may each include a titanium nitride and tungsten (TiN/W) stack in which titanium nitride and tungsten are sequentially stacked. The first conductive lines 30 may each include an N-type work function material or a P-type work function material. The N-type work function material may have a low work function of approximately 4.5 eV or less, and the P-type work function material may have a high work function of approximately 4.5 eV or greater.

Each of the second inter-cell dielectric layers 28 may be disposed between a plurality of first conductive lines 30 in the first direction D1. Each of the first conductive lines 30 that horizontally extend in the third direction D3 may simultaneously surround the horizontal sheets 13N at the same level. The first conductive lines 30 surrounding the horizontal sheets 13N may be referred to also as “gate-all-around (GAA) electrodes”. The horizontal sheets 13N may be referred to also as “nano sheet channels”, “nano wires” or “nano wire channels”.

Side gaps 30G may be defined between the first conductive lines 30 and the supporters 22 in the second direction D2. Each side gap 30G may be defined between a first conductive line 30 and a corresponding supporter 22 in the second direction D2.

Referring to FIGS. 14A to 16F as described above, portions of the first spacer layer 27A may be replaced with the first conductive lines 30, and the other portions may remain as the first spacers 27.

Referring back to FIGS. 16A and 16D, the side gaps 30G may expose all horizontal sheets 13N and the nano sheet dielectric layer 26, which are adjacent to each other in the third direction D3.

Referring back to FIGS. 16A and 16E, each of the horizontal sheets 13N may be disposed between the supporters 22 adjacent to each other in the third direction D3. Edges of the horizontal sheets 13N may be supported by the supporters 22.

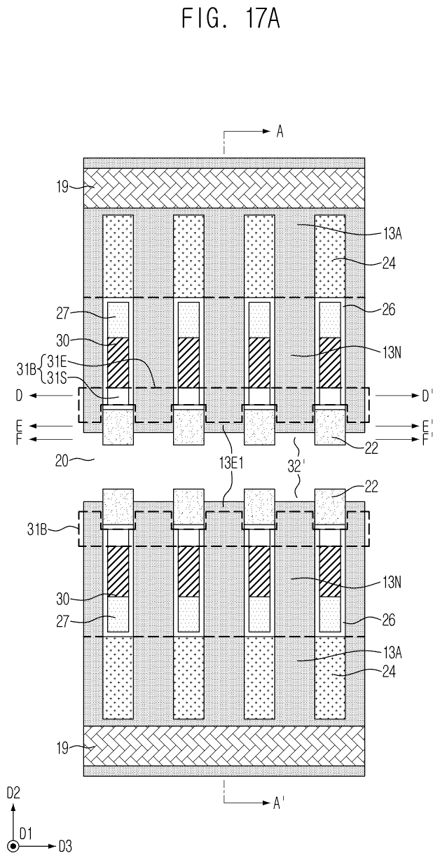

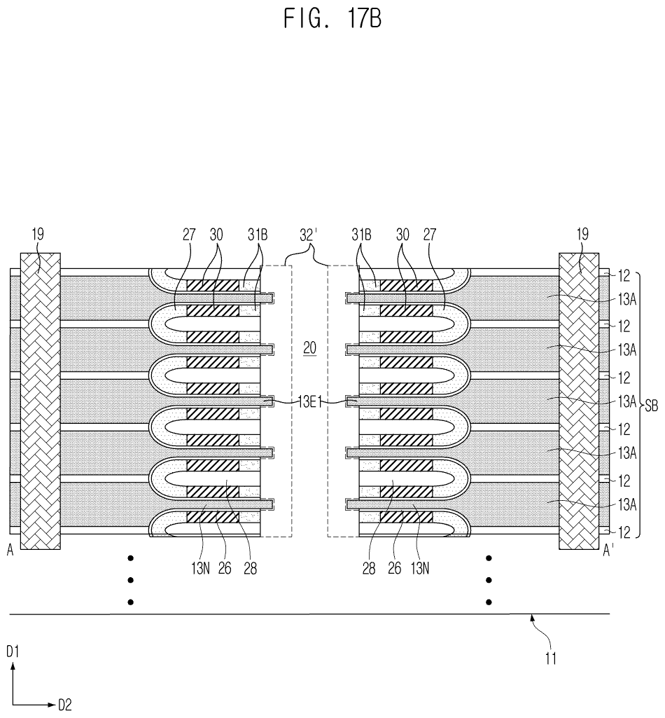

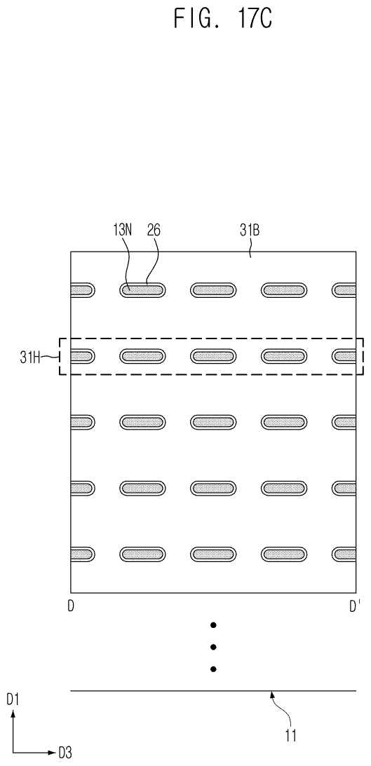

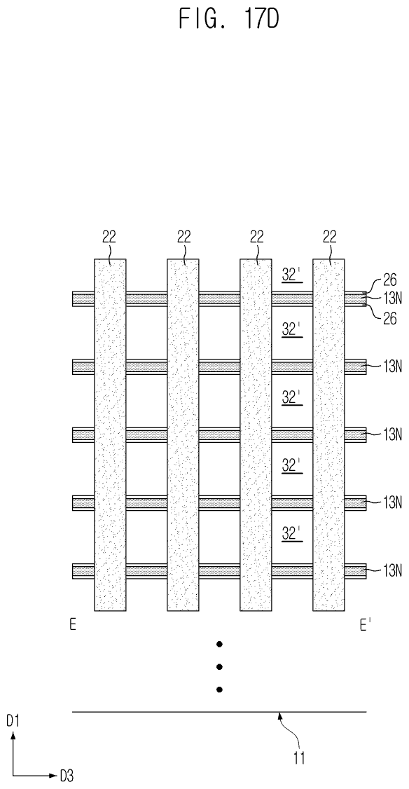

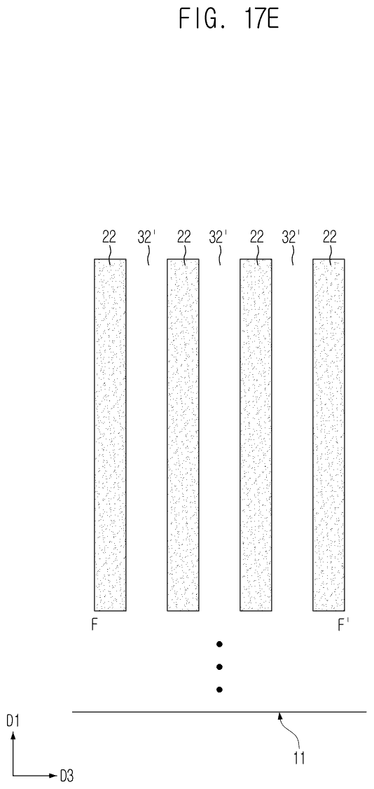

FIG. 17A is a plan view illustrating the structure at the horizontal sheet level for describing a method of forming a second spacer 31B. FIG. 17B is a cross-sectional view of the structure taken along line A-A′ illustrated in FIG. 17A. FIG. 17C is a cross-sectional view of the structure taken along line D-D′ illustrated in FIG. 17A. FIG. 17D is a cross-sectional view of the structure taken along line E-E′ illustrated in FIG. 17A. FIG. 17E is a cross-sectional view of the structure taken along line F-F′ illustrated in FIG. 17A.

Referring to FIGS. 17A to 17E, the second spacer 31B may be formed on one side of each of the first conductive lines 30. The second spacer 31B may include, for example, silicon oxide, silicon nitride, silicon carbon oxide, an embedded air gap, or a combination thereof. A process for forming the second spacer 31B may include first depositing a spacer material and then performing a side recessing process on the spacer material. The second spacer 31B may fill the side gaps (reference numeral “30G” of FIG. 16A) on sides of the first conductive lines 30. Portions of the second inter-cell dielectric layers 28 and portions of the nano sheet dielectric layer 26 may be recessed while or after the second spacer 31B is formed. The second spacer 31B may be self-aligned with edges of the second inter-cell dielectric layers 28. As the second inter-cell dielectric layers 28 and the nano sheet dielectric layer 26 are recessed, protruding edges 13E1 of the horizontal sheets 13N may be exposed.

The second spacer 31B may be disposed on upper and lower surfaces of portions of the horizontal sheets 13N between the second inter-cell dielectric layers 28. The second spacer 31B may include inner spacers 31S disposed between the horizontal sheets 13N in the third direction D3 and outer spacers 31E disposed on side surfaces of the supporters 22. The outer spacers 31E may be continuous from the inner spacer 31S. The inner spacer 31S may vertically extend in the first direction D1. The outer spacers 31E may be disposed on the upper and lower surfaces of portions of the horizontal sheets 13N on the nano sheet dielectric layer 26. That is, the outer spacers 31E may be mutually discontinuous in the first direction D1. The first spacer 27 and the second spacer 31B may have different shapes.

The second spacer 31B extending in the first direction D1 and the third direction D3 may have a frame structure surrounding portions of the horizontal sheets 13N. The second spacer 31B may include horizontal segments 31H. The horizontal segments 31H of the second spacer 31B may refer to portions extending in the third direction D3 by combinations of the inner spacers 31S and the outer spacers 31E. The horizontal segments 31H of the second spacer 31B may surround portions of the horizontal sheets 13N at the same horizontal level arranged in the third direction D3.

As above, the second spacer 31B may extend in the first direction D1 and the third direction D3 and may also surround portions of the horizontal sheets 13N by the horizontal segments 31H and the inner spacers 31S.

The second spacer 31B, the first conductive line 30 and the first spacer 27 may be disposed in the second direction D2 between the horizontal sheets 13N at the same horizontal level. In addition, the second spacer 31B, the first conductive line 30 and the first spacer 27 may be disposed in the second direction D2 between the supporters 22 and the first inter-cell dielectric layers 24.

After the second spacer 31B is formed, initial inter-supporter openings exposing the protruding edges 13E1 of the horizontal sheets 13N may be defined.

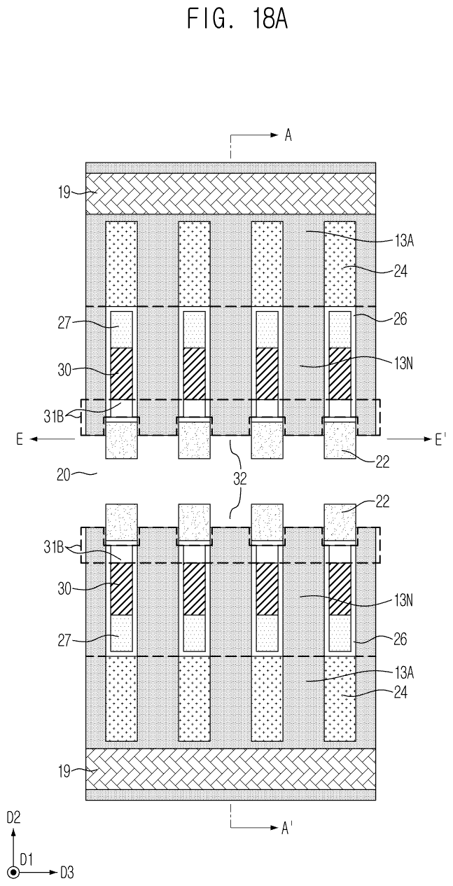

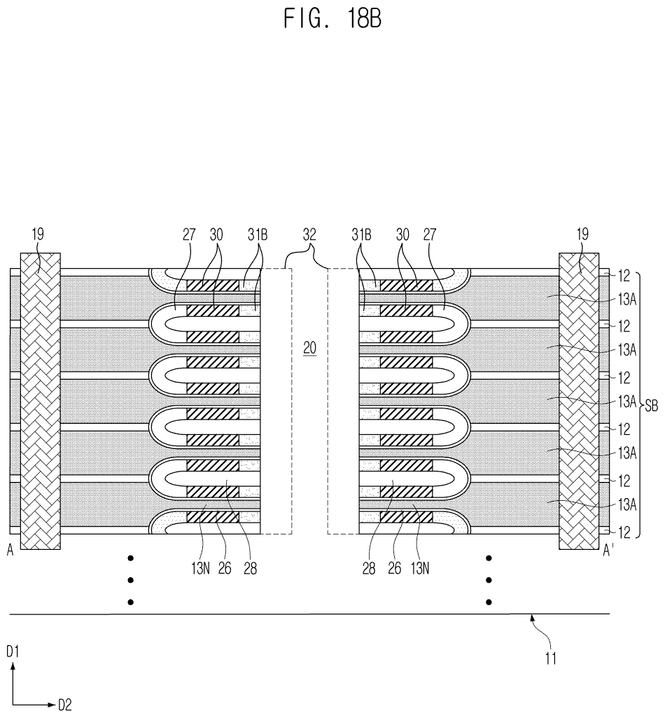

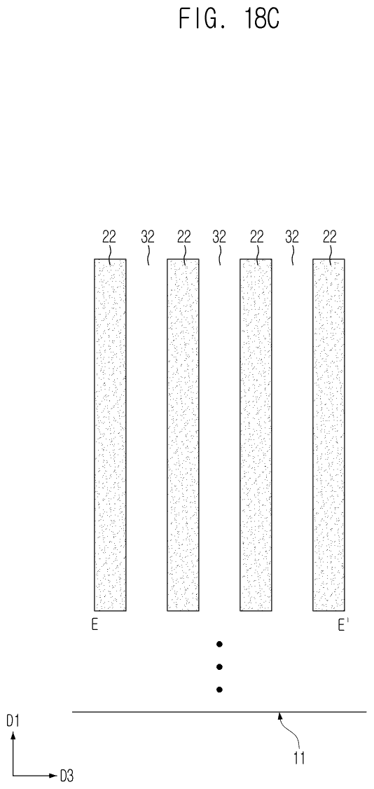

FIG. 18A is a plan view illustrating the structure at the horizontal sheet level for describing a method of forming inter-supporter openings 32. FIG. 18B is a cross-sectional view of the structure taken along line A-A′ illustrated in FIG. 18A. FIG. 18C is a cross-sectional view of the structure taken along line E-E′ illustrated in FIG. 18A.

Referring to FIGS. 18A to 18C, the protruding edges 13E1 of the horizontal sheets 13N may be cut to form the inter-supporter openings 32. By cutting the protruding edges 13E1 of the horizontal sheets 13N, the initial inter-supporter openings 32′ may expand horizontally to become the inter-supporter openings 32.

Forming the inter-supporter openings 32 may include cutting the protruding edges 13E1 of the horizontal sheets 13N in the second direction D2 from the first linear opening 20. A series of processes for forming the inter-supporter openings 32 may be performed using the second spacer 31B as a barrier.

As the inter-supporter openings 32 are formed, horizontal lengths of the horizontal sheets 13N may be shortened. The inter-supporter openings 32 may include inner sides which may expose the side surfaces of the horizontal sheets 13N. The inter-supporter openings 32 may be self-aligned with the supporters 22 and the outer spacers 31E of the second spacer 31B. The inter-supporter openings 32 may be referred to also as “self-aligned openings”.

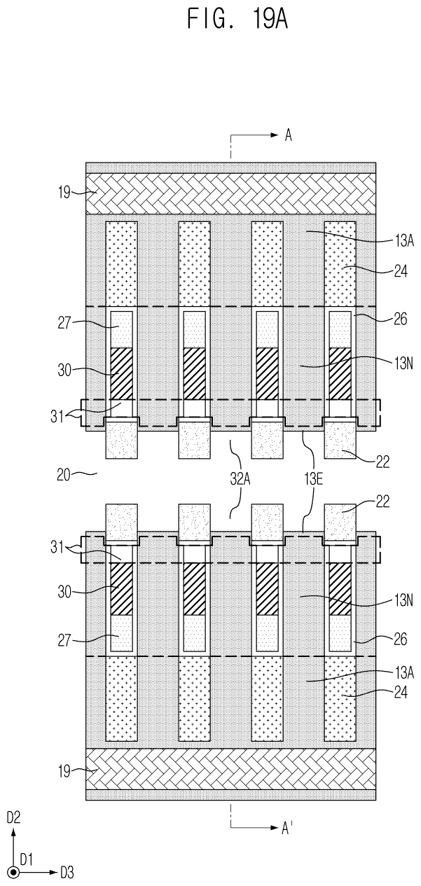

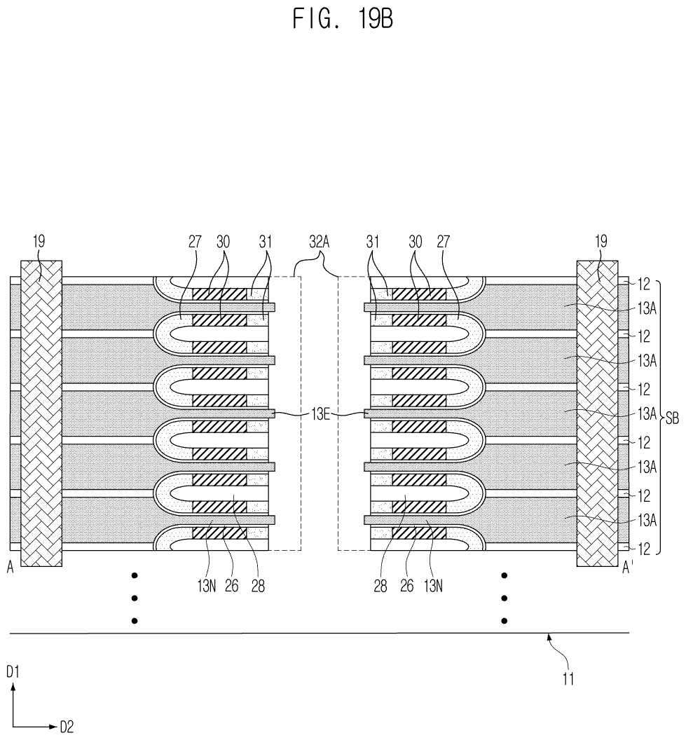

FIG. 19A is a plan view illustrating the structure at the horizontal sheet level for describing a method of additionally expanding the inter-supporter openings 32. FIG. 19B is a cross-sectional view of the structure taken along line A-A′ illustrated in FIG. 19A.

Referring to FIGS. 19A and 19B, the inter-supporter openings 32 may horizontally expand to form larger openings as shown by reference numeral “32A”. The second spacer 31B may be horizontally recessed to form the expanding inter-supporter openings 32A. Accordingly, a horizontal length of the second spacer may be reduced, as indicated by reference numeral “31”. The inter-supporter openings 32A may expose protruding sheet nodes 13E of the horizontal sheets 13N. The protruding sheet nodes 13E may not be aligned with the outer surfaces of the second spacer 31 and may have a horizontally protruding shape.

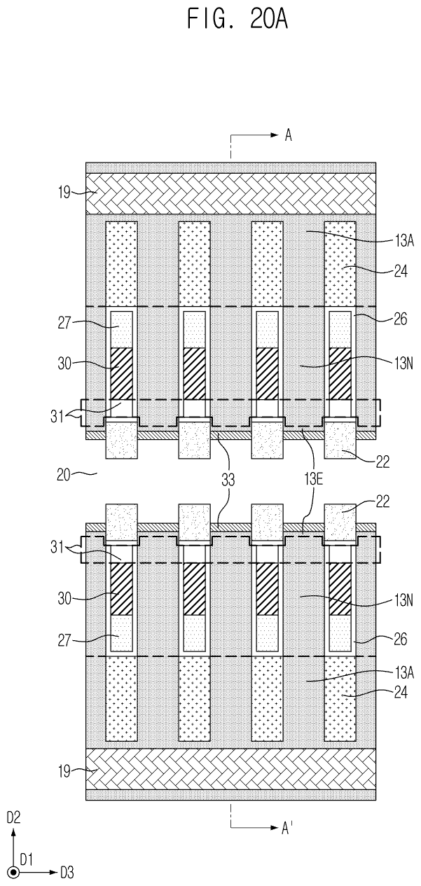

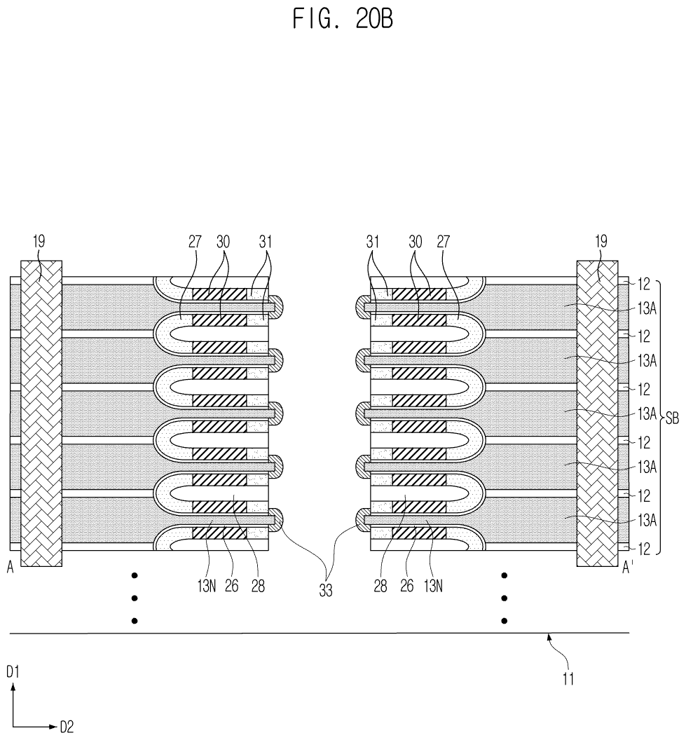

FIG. 20A is a plan view illustrating the structure at the horizontal sheet level for describing a method of forming first contact nodes 33. FIG. 20B is a cross-sectional view of the structure taken along line A-A′ illustrated in FIG. 20A.

Referring to FIGS. 20A and 20B, the first contact nodes 33 may be formed in the inter-supporter openings 32A. The first contact nodes 33 may be formed by depositing and etching doped polysilicon. For example, forming the first contact nodes 33 may include depositing doped polysilicon such that the first thickness covering the protruding sheet nodes 13E is greater than the second thickness formed on other surfaces, and etching the doped polysilicon to form the first contact nodes 33. In another embodiment, the first contact nodes 33 may be selectively formed on the protruding sheet nodes 13E by epitaxial growth.

The first contact nodes 33 may be disposed in the inter-supporter openings 32A and cover the protruding sheet nodes 13E of the horizontal sheets 13N.

The first contact nodes 33 may each include a dopant. The first contact nodes 33 may each include an N-type dopant. The N-type dopant may include phosphorus, arsenic, antimony, or a combination thereof.

In some embodiments, first doped regions (refer to reference symbol “DR” of FIG. 1B) may be formed in the horizontal sheets 13N. A heat treatment process may be performed to form the first doped regions, thereby allowing dopants to diffuse from the first contact nodes 33.

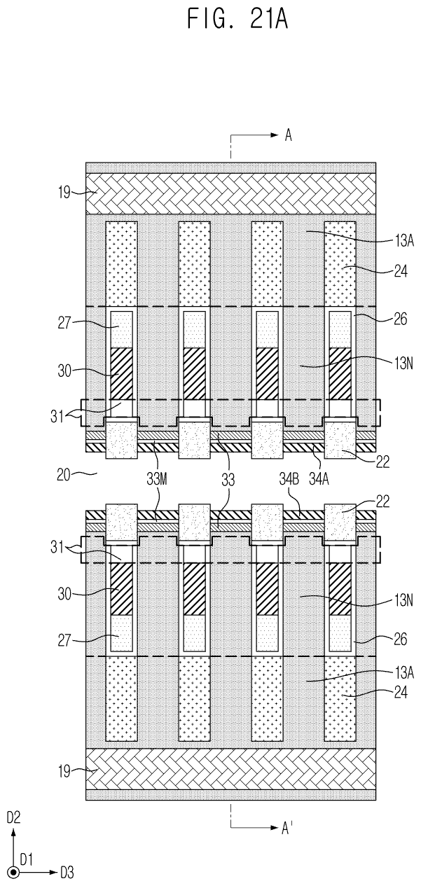

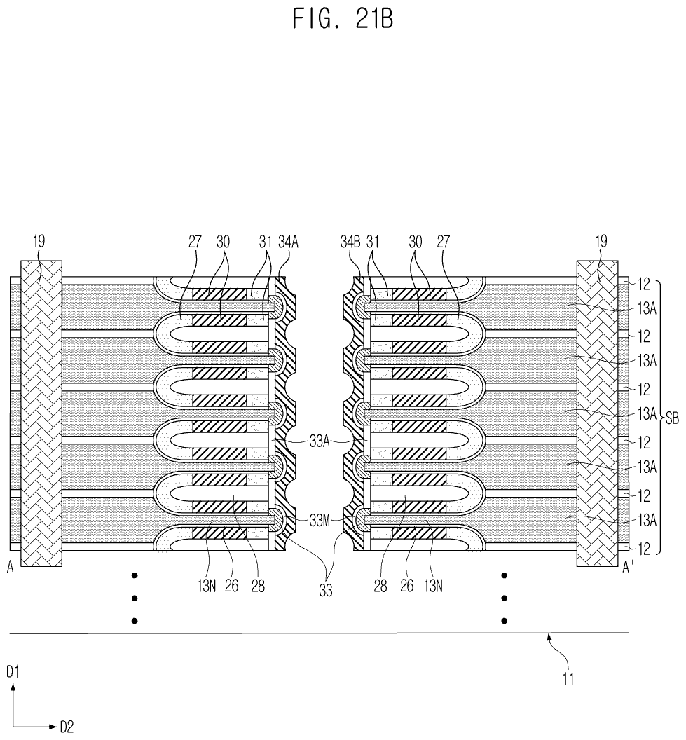

FIG. 21A is a plan view illustrating the structure at the horizontal sheet level for describing a method of forming second conductive lines 34A and 34B. FIG. 21B is a cross-sectional view of the structure taken along line A-A′ illustrated in FIG. 21A.

Referring to FIGS. 21A and 21B, contact isolation layers 33A may be formed on the first contact nodes 33. The contact isolation layers 33A may be formed between the first contact nodes 33 in the first direction D1. The contact isolation layers 33A may isolate the first contact nodes 33 from one another in the first direction D1. The contact isolation layers 33A may each include a dielectric material. Forming the contact isolation layers 33A may include forming a dielectric material on the first contact nodes 33 and etching the dielectric material.

The contact isolation layers 33A may expose the outer surfaces of the first contact nodes 33.

Subsequently, ohmic contact layers 33M may be formed on the first contact nodes 33. For example, the ohmic contact layers 33M may each include metal silicide. Forming the ohmic contact layers 33M may include forming a metal material on the outer surfaces of the first contact nodes 33, performing a heat treatment to induce a silicide reaction between the metal material and the outer surfaces of the first contact nodes 33, and removing an unreacted metal material. In some embodiments, the unreacted metal material may remain without being removed.

Subsequently, the second conductive lines 34A and 34B may be formed on the ohmic contact layers 33M and the contact isolation layers 33A. The second conductive lines may include a first vertical conductive line 34A and a second vertical conductive line 34B. The first vertical conductive line 34A and the second vertical conductive line 34B may be spaced apart from each other. The first vertical conductive line 34A may be coupled in common to the first contact nodes 33 and the ohmic contact layers 33M disposed in the first direction D1. The second vertical conductive line 34B may be coupled in common to the first contact nodes 33 and the ohmic contact layers 33M disposed in the first direction D1.

The first and second vertical conductive lines 34A and 34B may each include a metal-based material. The first and second vertical conductive lines 34A and 34B may each include titanium nitride, tungsten, or a combination thereof. The first and second vertical conductive lines 34A and 34B may cover the first contact nodes 33 and the ohmic contact layers 33M. The first and second vertical conductive lines 34A and 34B may correspond to the first and second vertical conductive lines BLA and BLB illustrated in FIGS. 4A and 4B.

Forming the first and second vertical conductive lines 34A and 34B may include depositing a vertical conductive line material and performing an etch-back process on the vertical conductive line material. That is, the first and second vertical conductive lines 34A and 34B may be formed to be self-aligned with the supporters 22 through a blanket etch-back process without a mask.

Bottom portions of the first vertical conductive lines 34A and bottom portions of the second vertical conductive lines 34B may be discontinuous to each other or may be merged with each other. The first and second vertical conductive lines 34A and 34B may vertically extend in the first direction D1. Outer surfaces of the first and second vertical conductive lines 34A and 34B may have non-linear profiles. In another embodiment, the outer surfaces of the first and second vertical conductive lines 34A and 34B may have linear profiles.

The first and second vertical conductive lines 34A and 34B may be formed to be self-aligned with the second spacer 31 and the supporters 22. The first and second vertical conductive lines 34A and 34B may be disposed between the supporters 22 in the third direction D3. The supporters 22 may support the first and second vertical conductive lines 34A and 34B. The supporters 22 may serve as isolation layers between the first and second vertical conductive lines 34A and 34B adjacent to each other in the third direction D3.

The first and second vertical conductive lines 34A and 34B which are formed to be self-aligned with the supporters 22 and the second spacer 31 may be referred to as a “self-aligned bit line (SABL) structure”.

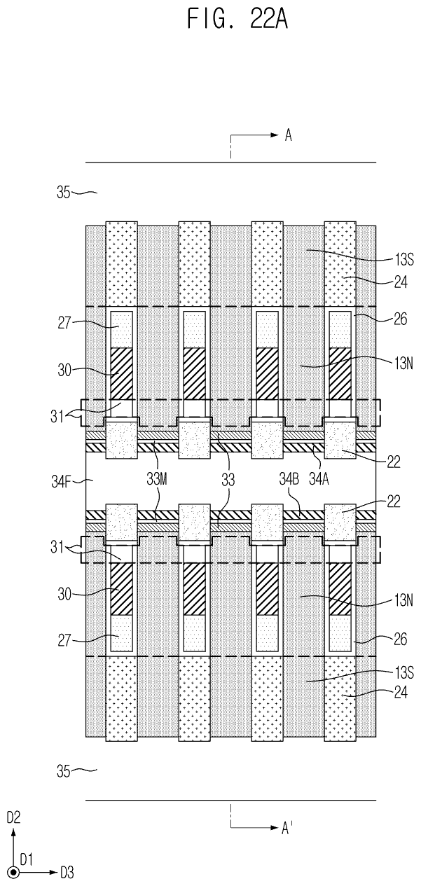

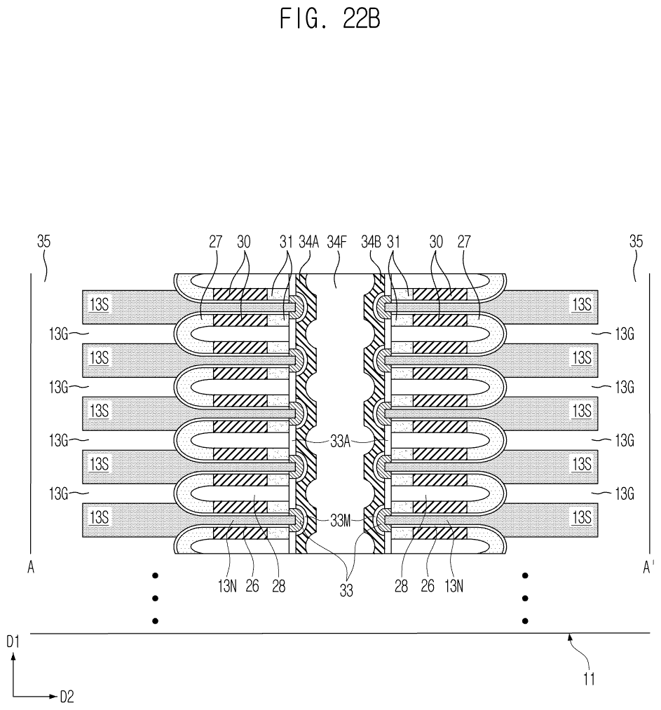

FIG. 22A is a plan view illustrating the structure at the horizontal sheet level for describing a method of forming second linear openings 35. FIG. 22B is a cross-sectional view of the structure taken along line A-A′ illustrated in FIG. 22A.

Referring to FIGS. 22A and 22B, an array isolation layer 34F may be formed to fill the first linear opening 20 on the first and second vertical conductive lines 34A and 34B. The array isolation layer 34F may vertically extend in the first direction D1 and horizontally extend in the third direction D3. The first and second vertical conductive lines 34A and 34B adjacent to each other in the third direction D3 may be isolated from each other by the array isolation layer 34F. The array isolation layer 34F may include a dielectric material. The array isolation layer 34F may include silicon oxide, silicon nitride, an air gap, or a combination thereof.

Subsequently, the second linear sacrificial layer 19L may be removed. Accordingly, the second linear openings 35 may be formed.

After the second linear openings 35 are formed, the sacrificial mold layers 12 may be selectively recessed through the second linear openings 35. To selectively recess the sacrificial mold layers 12, a difference in etch selectivity between the sacrificial mold layers 12 and the body sheets 13A may be used. The sacrificial mold layers 12 may be removed using a wet etch or dry etch process. For example, when the sacrificial mold layers 12 include a silicon germanium layer, the body sheets 13A include a monocrystalline silicon layer, and the silicon germanium layer may be etched by using an etchant or etch gas having a selectivity with respect to the monocrystalline silicon layer.

Subsequently, the body sheets 13A may be recessed in vertical and horizontal directions. To recess the body sheets 13A, the wet etch or dry etch process may be used. Vertical thicknesses of the body sheets 13A may be reduced, as indicated by reference numeral “13S”.

Each of inter-body recesses 13G may be formed between the body sheets 13A that are vertically disposed. Inner sides of the inter-body recesses 13G may expose a surface of the nano sheet dielectric layer 26.

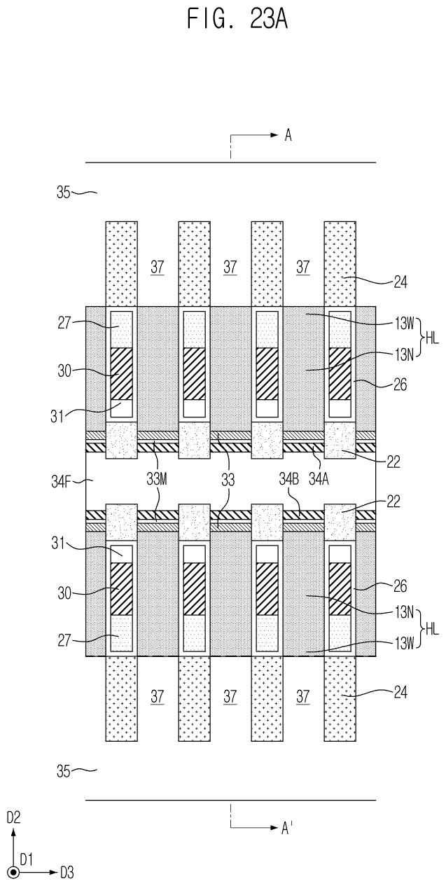

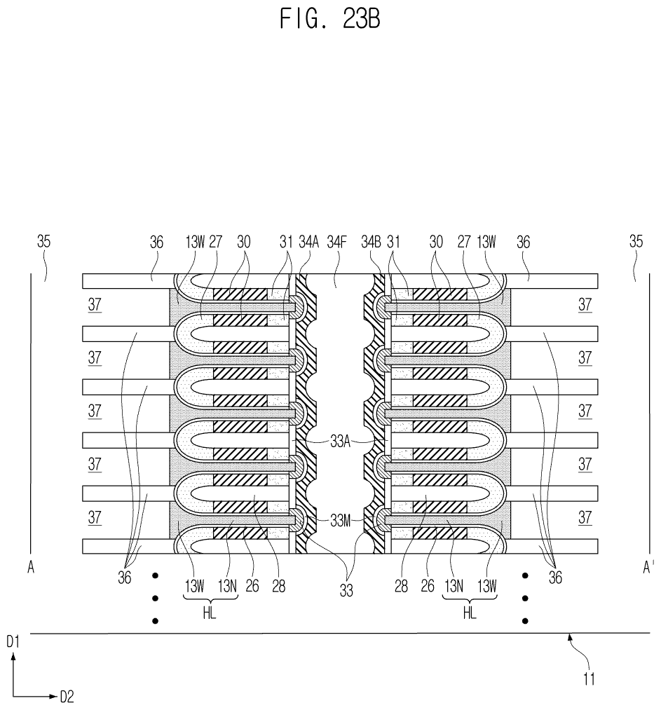

FIG. 23A is a plan view illustrating the structure at the horizontal sheet level for describing a method of forming tapered sheets 13W. FIG. 23B is a cross-sectional view of the structure taken along line A-A′ illustrated in FIG. 23A.

Referring to FIGS. 23A and 23B, third inter-cell dielectric layers 36 may be formed to fill the inter-body recesses 13G. The third inter-cell dielectric layers 36 may each include silicon oxide. The third inter-cell dielectric layers 36 may be referred to also as “inter-data storage element dielectric layers”.

Combinations of the third inter-cell dielectric layers 36 and the first inter-cell dielectric layers 24 may be inter-cell dielectric layers each having a lattice-shaped frame structure.

After the third inter-cell dielectric layers 36 are formed, storage slots 37 may be formed by the horizontal recessing (or trimming) of the body sheets 13S. The storage slots 37 may be referred to also as “capacitor openings”. Tapered sheets 13W may be formed by the horizontal recessing of the body sheets 13S. The tapered sheets 13W may include tapered profiles 13T.

Nano sheets HL may be formed by combinations of the horizontal sheet 13N and the tapered sheet 13W. In some embodiments, the body sheets 13S may be fully recessed so that upper and lower surfaces of the tapered sheets 13W may be composed only of the tapered profiles 13T.

Each of the nano sheets HL may include the horizontal sheet 13N and the tapered sheet 13W. The tapered sheet 13W may refer to the body sheet 13S remaining after the recessing. An average vertical height of the tapered sheet 13W of the nano sheet HL in the first direction D1 may be greater than an average vertical height of the horizontal sheet 13N. A thickness of the tapered sheet 13W of the nano sheet HL may gradually increase in the second direction D2. A horizontal length of the tapered sheet 13W in the second direction D2 may be less than a horizontal length of the horizontal sheet 13N. A cross section of the tapered sheet 13W of the nano sheet HL may have a fan-like shape. The tapered sheet 13W may be referred to as a “fan-shaped sheet”, and the horizontal sheet 13N may be referred to as a “flat plate-shaped sheet”.

Forming the nano sheets HL (each including the tapered sheet 13W) may include etching the body sheets 13S. The etching may include isotropic and/or anisotropic etching. One side of the tapered sheet 13W, i.e., the side exposed by each of the storage slots 37, may have a flat shape. However, the one side of the tapered sheet 13W may have various shapes and is not limited to a flat shape.

Each of the nano sheets HL may include a first edge and a second edge. The first edge may refer to a side surface of the horizontal sheet 13N electrically coupled to the first and second vertical conductive lines 34A and 34B and the first contact node 33. The second edge may refer to a side surface of the tapered sheet 13W exposed by the storage slot 37.

Each storage slot 37 may be disposed in the lattice-shaped frame structure formed by the combination of the third inter-cell dielectric layer 36 and the first inter-cell dielectric layer 24.

In some embodiments, the horizontal recessing of the body sheets 13S for forming the tapered sheets 13W may terminate at the boundary area between the horizontal sheet 13N and the tapered sheet 13W. For example, the horizontal recessing of the body sheets 13S may continue until a vertical thickness of the tapered sheet 13W becomes equal to a vertical thickness of the horizontal sheet 13N.

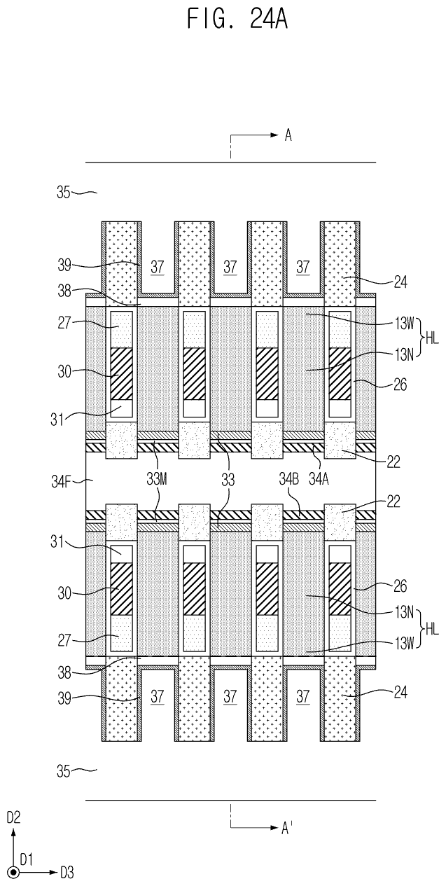

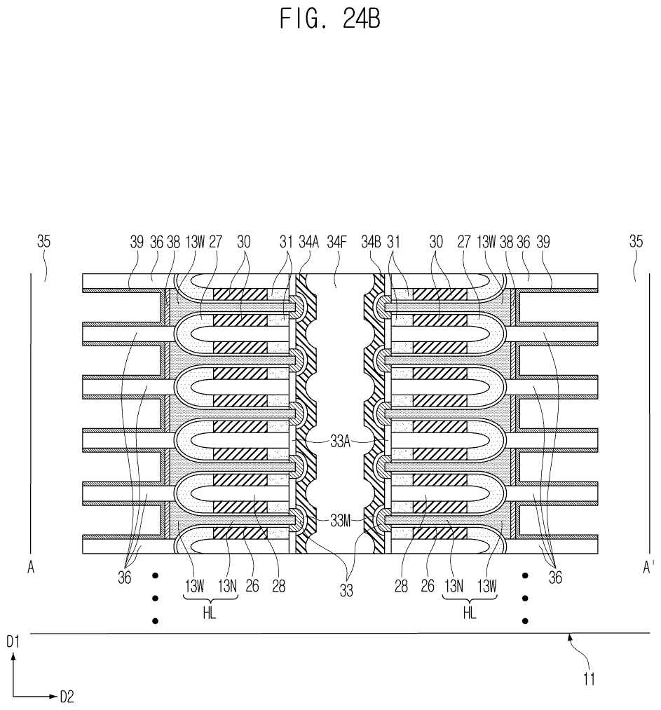

FIG. 24A is a plan view illustrating the structure at a nano sheet level for describing a method of forming second contact nodes 38 and first electrodes 39. FIG. 24B is a cross-sectional view illustrating the structure taken along line A-A′ illustrated in FIG. 24A.

Referring to FIGS. 24A and 24B, a pre-cleaning process may be performed on the exposed surfaces of the tapered sheets 13W.

Subsequently, the second contact nodes 38 may be formed on the tapered sheets 13W. Forming the second contact nodes 38 may include selective epitaxial growth (SEG). For example, a semiconductive material may be grown from the side surfaces of the tapered sheets 13W through the SEG. The second contact nodes 38 may each include SEG Si. Because the tapered sheets 13W each include monocrystalline silicon, a silicon layer may be epitaxially grown along crystal surfaces of the side surfaces of the tapered sheets 13W.

The second contact nodes 38 may incorporate a dopant introduced in situ during silicon layer growth via selective epitaxial growth (SEG). Accordingly, the second contact nodes 38 may each be a doped epitaxial layer. The second contact nodes 38 may each include an N-type dopant as the dopant. The N-type dopant may include phosphorus, arsenic, antimony, or a combination thereof. The second contact nodes 38 may each include a phosphorus-doped silicon epitaxial layer formed by the SEG, i.e., doped SEG SiP.

Because the second contact nodes 38 are formed using the SEG, void-free or seam-free second contact nodes 38 may be formed. Because the second contact nodes 38 are formed using the SEG, a process for forming the second contact nodes 38 may be simplified.

Each of the second contact nodes 38 may be disposed between the third inter-cell dielectric layers 36 that are vertically stacked.

In some embodiments, the second contact nodes 38 may be formed by depositing and etching doped polysilicon.

In some embodiments, second doped regions (refer to reference numeral “SR” of FIG. 1B) may be formed in the tapered sheets 13W. A heat treatment process may be performed to form the second doped regions, so that the dopants may be diffused from the second contact nodes 38.

Each of the nano sheets HL may include the horizontal sheet 13N and the tapered sheet 13W. The nano sheets HL may correspond to the nano sheets HL described above with reference to FIGS. 1A to 4D. Each of the nano sheets HL may include the first doped region DR, the channel CH, and the second doped region SR, as described above with reference to FIG. 1B.

In some embodiments, an ohmic contact layer including metal silicide may be further formed after the second contact nodes 38 are formed.

Subsequently, storage nodes, that is, the first electrodes 39 of a data storage element, may be formed on the second contact nodes 38. The first electrodes 39 may each have a horizontally-oriented cylindrical shape. Each of the first electrodes 39 may be disposed in a different one of the storage slots 37. The first electrodes 39 adjacent to each other in the second direction D2 may be spaced apart from each other by the second linear openings 35. The first electrodes 39 adjacent to each other in the third direction D3 may be spaced apart from each other by the first inter-cell dielectric layers 24. The first electrodes 39 adjacent to each other in the first direction D1 may be spaced apart from each other by the third inter-cell dielectric layers 36. Forming the first electrodes 39 may include depositing a metal material, gap-filling a sacrificial material, and isolating the metal material in a vertical/horizontal direction. The sacrificial material may include oxide or polysilicon.

Each of the first electrodes 39 may include an inner space and a plurality of outer surfaces. The inner space of the first electrode 39 may include a plurality of inner surfaces. The outer surfaces of the first electrode 39 may include a vertical outer surface and a plurality of horizontal outer surfaces. The vertical outer surface of the first electrode 39 may vertically extend in the first direction D1. The horizontal outer surfaces of the first electrode 39 may horizontally extend in the second direction D2 or the third direction D3. The inner space of the first electrode 39 may be a three-dimensional space. The first electrode 39 may have a cylindrical shape.

The first electrode 39 may include metal, noble metal, metal nitride, conductive metal oxide, conductive noble metal oxide, metal carbide, metal silicide, or a combination thereof. For example, the first electrode 39 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof.

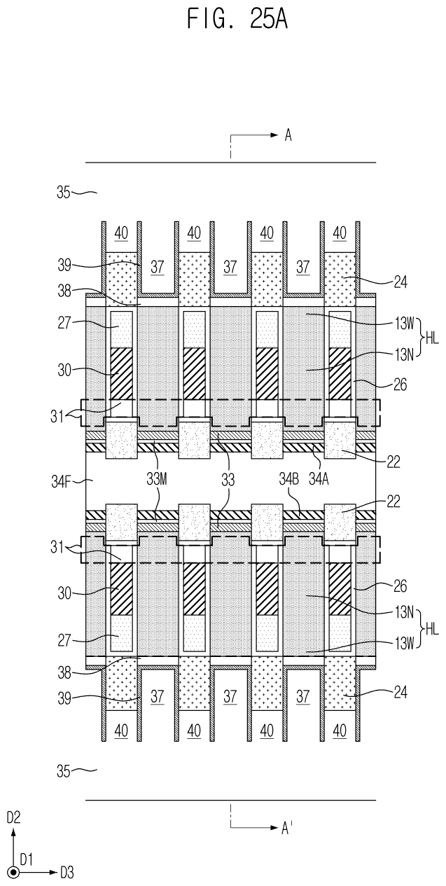

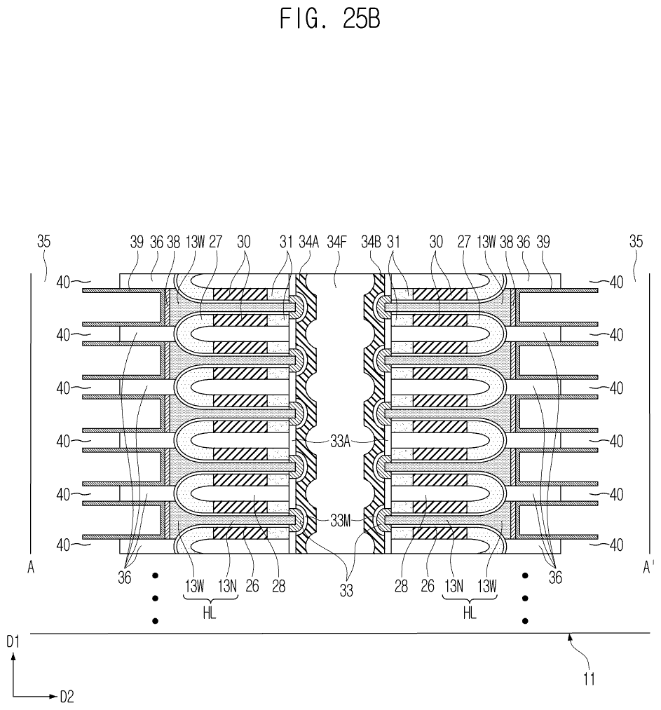

FIG. 25A is a plan view illustrating the structure at the nano sheet level for describing a method of recessing the first and third inter-cell dielectric layers 24 and 36. FIG. 25B is a cross-sectional view of the structure taken along line A-A′ illustrated in FIG. 25A.

Referring to FIGS. 25A and 25B, portions of the first and third inter-cell dielectric layers 24 and 36 may be horizontally recessed (refer to reference numeral “40”). Accordingly, outer walls of the first electrodes 39 may be partially exposed. The first electrodes 39 may each have a semi-cylindrical shape. Horizontal recess depths of the first and third inter-cell dielectric layers 24 and 36 may be depths that do not expose the second contact nodes 38. The semi-cylindrical shape of each of the first electrodes 39 may include cylindrical inner surfaces and semi-cylindrical outer surfaces.

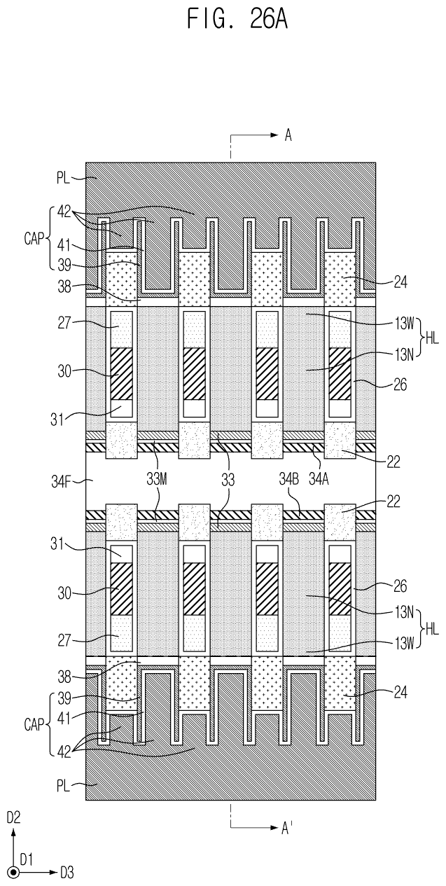

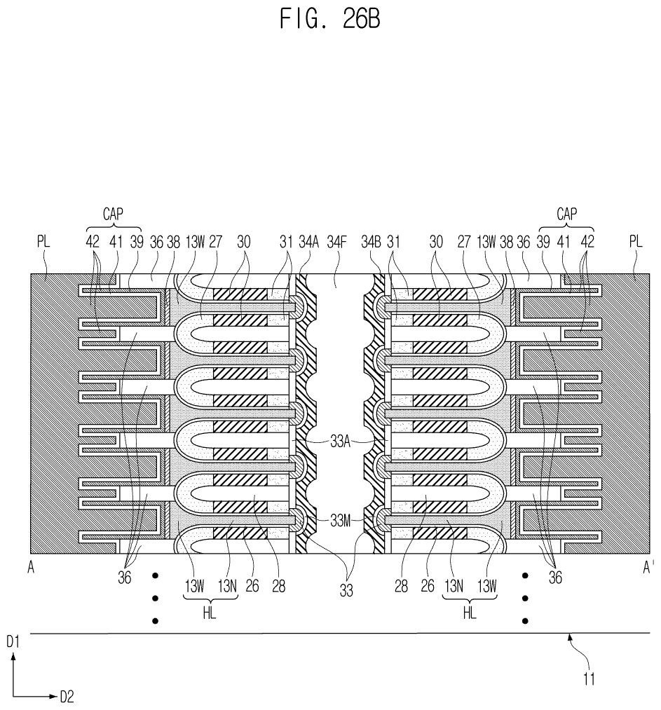

FIG. 26A is a plan view illustrating the structure at the nano sheet level for describing a method of forming a second electrode 42 of the data storage element. FIG. 26B is a cross-sectional view of the structure taken along line A-A′ illustrated in FIG. 26A.

Referring to FIGS. 26A and 26B, a dielectric layer 41 and the second electrode 42 may be sequentially formed on the first electrodes 39. The first electrode 39, the dielectric layer 41 and the second electrode 42 may be a data storage element CAP. The second electrodes 42 of the data storage elements CAP may be merged with one another and form a common plate PL. The dielectric layer 41 and the second electrode 42 may correspond to the dielectric layer DE and the second electrode PN illustrated in FIGS. 4A and 4B. The second electrode 42 may be a plate node.

The dielectric layer 41 and the second electrode 42 may be disposed on the cylindrical inner surfaces of the first electrode 39. A portion of the dielectric layer 41 and a portion of the second electrode 42 may extend to be disposed on the semi-cylindrical outer surfaces of the first electrode 39.

The dielectric layer 41 may be referred to as a “capacitor dielectric layer” or a “memory layer”. The dielectric layer 41 may include silicon oxide, silicon nitride, a high-k material, a ferroelectric material, an antiferroelectric material, a perovskite material, or a combination thereof. The dielectric layer 41 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 41 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, an HA (HfO₂/Al₂O₃) stack, an HAH (HfO₂/Al₂O₃/HfO₂) stack, an HAHA (HfO₂/Al₂O₃/HfO₂/Al₂O₃) stack, an HAHAH (HfO₂/Al₂O₃/HfO₂/Al₂O₃/HfO₂) stack, an HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, an HZHZ (HfO₂/ZrO₂/HfO₂/ZrO₂) stack, or an AHZAZHA (Al₂O₃/HfO₂/ZrO₂/Al₂O₃/ZrO₂/HfO₂/Al₂O₃) stack.

The second electrode 42 may include metal, noble metal, metal nitride, conductive metal oxide, conductive noble metal oxide, metal carbide, metal silicide, or a combination thereof. For example, the second electrode 42 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode 42 may also include a combination of a metal-based material and a silicon-based material. For example, a titanium nitride, tungsten and polysilicon may be sequentially stacked in the second electrode 42.

In some embodiments, a plurality of interface control layers may be further included between the first electrode 39 and the dielectric layer 41 and between the dielectric layer 41 and the second electrode 42 to alleviate leakage current. Each of the interface control layers may include titanium oxide (TiO₂), tantalum oxide (Ta₂O₅), niobium oxide (Nb₂O₅), niobium nitride (NbN), niobium oxynitride (NbON), or a combination thereof. The data storage element CAP may include a first interface control layer, a second interface control layer, or a combination thereof. The first interface control layer and the second interface control layer may be conductive or dielectric. The first interface control layer may be formed between the first electrode 39 and the dielectric layer 41, and the second interface control layer may be formed between the dielectric layer 41 and the second electrode 42. The first interface control layer and the second interface control layer may be made of the same material or different materials. For example, a structure in which the first interface control layer, dielectric layer 41 and second interface control layer of the data storage element CAP are sequentially stacked may include an NZHZAZHZATN (Nb₂O₅/ZrO₂/HfO₂/ZrO₂/Al₂O₃/ZrO₂/HfO₂/ZrO₂/Al₂O₃/TiO₂/Nb₂O 5) stack.

In some embodiments, the recessing of the first and third inter-cell dielectric layers 24 and 36 illustrated in FIGS. 25A and 25B may be omitted. Thereafter, as illustrated in FIGS. 26A and 26B, the dielectric layer 41 and the second electrode 42 may be formed. Accordingly, the data storage element CAP including the first electrode 39 having a concave shape may be formed.

The first electrodes 39 of the data storage elements CAP may be disposed in the storage slots 37 and may also be coupled to the tapered sheets 13W.

Referring to FIGS. 5A to 26B, the method for fabricating the semiconductor device may include forming a vertical stack of the mold layers 13, forming the sacrificial isolation layers 16 between the mold layers 13 in the vertical stack, replacing edges of the sacrificial isolation layers 16 with the supporters 22, forming vertical and horizontal arrangements of pre-nano sheet layers each including the horizontal sheet 13N including the protruding edge 13E1 contacting the supporters 22 and the body sheet 13A continuous from the horizontal sheet 13N through the recessing of the mold layers 13, replacing the sacrificial isolation layers 16 with the second inter-cell dielectric layers 28, forming the first conductive lines 30 that are horizontally oriented while surrounding portions of the horizontal sheets 13N between the second inter-cell dielectric layers 28 and the supporters 22, forming the protruding sheet nodes 13E between the supporters 22 by cutting the protruding edges 13E1 of the horizontal sheets 13N, and forming a horizontal arrangement of the second conductive lines 34A and 34B electrically coupled to the protruding sheet nodes 13E and vertically oriented between the supporters 22 in a direction intersecting the first conductive lines 30.

According to various embodiments of the present disclosure, because the second conductive lines 34A and 34B are self-aligned with the supporters 22 and the second spacer 31, a high aspect ratio etch process is not required. Accordingly, it is possible to improve the degree of integration and reduce the fabrication cost of the semiconductor device.

According to various embodiments of the present disclosure, the electrical isolation between the second conductive lines 34A and 34B adjacent to each other is stable due to the supporters 22.

According to various embodiments of the present disclosure, because the first contact node 33 is formed of doped polysilicon, an effective area of the ohmic contact layer 33M may increase. Accordingly, it is possible to improve contact resistance between the second conductive lines 34A and 34B and the first contact node 33.

According to various embodiments of the present disclosure, because a gap between the first conductive lines 30 is partially filled with the second inter-cell dielectric layers 28, parasitic capacitance between the first conductive lines 30 may be reduced. Accordingly, the size of a memory cell mat may increase, which is advantageous for increasing a net die and reducing the fabrication cost of the semiconductor device. In addition, because the parasitic capacitance between the first conductive lines 30 is reduced, a timing characteristic tRCD (the time between an active command and a read command) of a semiconductor memory device such as a DRAM may be improved.

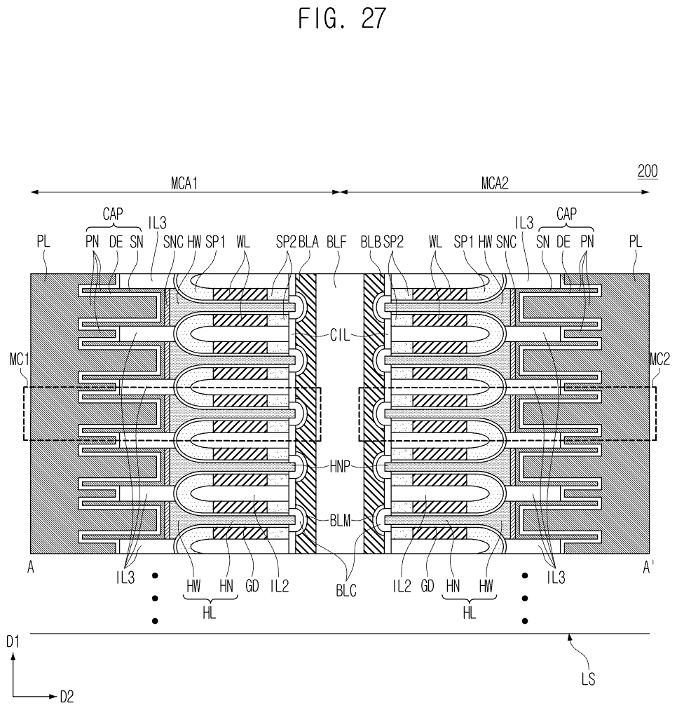

FIG. 27 is a schematic cross-sectional view of a semiconductor device according to another embodiment of the present disclosure. The semiconductor device 200 of FIG. 27 may be similar to the semiconductor device 100 of FIGS. 4A to 4D. Hereinafter, detailed descriptions of overlapping components are provided above with reference to FIGS. 4A to 4D.

As illustrated in FIG. 27, the semiconductor device 200 may include a lower structure LS and a memory cell array MCA. The memory cell array MCA may include a first sub-cell array MCA1 and a second sub-cell array MCA2. The first sub-cell array MCA1 may include a three-dimensional array of the first memory cells MC1. The second sub-cell array MCA2 may include a three-dimensional array of the second memory cells MC2. The first memory cells MC1 of the first sub-cell array MCA1 may share the second conductive line, i.e., the first vertical conductive line BLA. The second memory cells MC2 of the second sub-cell array MCA2 may share the second conductive line, i.e., the second vertical conductive line BLB. A bottom portion of the first vertical conductive line BLA may be electrically isolated from a bottom portion of the second vertical conductive line BLB. Outer surfaces of the first and second vertical conductive lines BLA and BLB may have a linear profile.

According to various embodiments of the present disclosure, electrical isolation between vertical conductive lines may be easily performed because a supporter is formed between the vertical conductive lines.

According to various embodiments of the present disclosure, an effective area of an ohmic contact layer may increase because a contact node is formed of doped polysilicon.

According to various embodiments of the present disclosure, it is possible to improve electrical characteristics and reliability of a semiconductor device.

While specific embodiments of the present disclosure have been illustrated and described with respect to the drawings, the disclosed embodiments are not intended to be restrictive. Furthermore, it is noted that the embodiments may be achieved in various ways through substitution, change, and modification, as those skilled in the art will recognize in light of the present disclosure, without departing from the technical concepts and/or scope of the present disclosure and the following claims. Furthermore, the embodiments may be combined to form additional embodiments.

What is claimed is:

1. A semiconductor device comprising:
vertical and horizontal arrangements of nano sheets including horizontal sheets, which include protruding sheet nodes, and tapered sheets, which are continuous in a first horizontal direction from the horizontal sheets;
a vertical arrangement of first conductive lines that surround portions of the horizontal sheets in the horizontal arrangement and are oriented in a second horizontal direction;
first contact nodes covering the protruding sheet nodes of the horizontal sheets;
a horizontal arrangement of second conductive lines that cover the first contact nodes and are oriented in a vertical direction;
supporters that are disposed between the second conductive lines in the horizontal arrangement and are oriented in the vertical direction; and
data storage elements coupled to the tapered sheets.

2. The semiconductor device of claim 1, further comprising contact isolation layers that are disposed between the first contact nodes in the vertical direction and expose outer surfaces of the first contact nodes.

3. The semiconductor device of claim 2, further comprising ohmic contact layers that are disposed between the first contact nodes and the second conductive lines and cover the outer surfaces of the first contact nodes.

4. The semiconductor device of claim 1, wherein the supporters directly contact the second conductive lines, the first contact nodes and the protruding sheet nodes.

5. The semiconductor device of claim 1, wherein each of the supporters includes a dielectric material.

6. The semiconductor device of claim 1, wherein each of the first contact nodes includes doped polysilicon.

7. The semiconductor device of claim 1, further comprising:
a first spacer that is disposed between the data storage elements and the first conductive lines and surrounds the tapered sheets; and
a second spacer that is disposed between the first conductive lines and the first contact nodes and surrounds portions of the horizontal sheets.

8. The semiconductor device of claim 7, wherein the second spacer includes extension portions covering inner walls of the supporters.

9. The semiconductor device of claim 1, further comprising second contact nodes formed between the tapered sheets and the data storage elements.

10. The semiconductor device of claim 1, wherein the data storage elements include:
first electrodes coupled to the tapered sheets;
a dielectric layer disposed on the first electrodes; and
second electrodes disposed on the dielectric layer.

11. A method for fabricating a semiconductor device, the method comprising:
forming a vertical stack of mold layers;
forming sacrificial isolation layers between the mold layers in the vertical stack;
replacing one-side edges of the sacrificial isolation layers with supporters;
forming vertical and horizontal arrangements of pre-nano sheet layers including horizontal sheets including protruding edges, which contact the supporters through recessing of the mold layers, and body sheets, which are continuous from the horizontal sheets;
replacing the sacrificial isolation layers with inter-cell dielectric layers;
forming first conductive lines that surround portions of the horizontal sheets between the inter-cell dielectric layers and the supporters and are oriented horizontally;
forming protruding sheet nodes between the supporters by cutting protruding edges of the horizontal sheets; and
forming a horizontal arrangement of second conductive lines that are electrically coupled to the protruding sheet nodes and are vertically oriented between the supporters in a direction intersecting the first conductive lines.

12. The method of claim 11, further comprising:
before forming the second conductive lines,
forming a vertical arrangement of first contact nodes that cover the protruding sheet nodes;
forming contact isolation layers that expose outer surfaces of the first contact nodes between the first contact nodes in the vertical arrangement; and
forming ohmic contact layers that cover the outer surfaces of the first contact nodes.

13. The method of claim 12, wherein forming the first contact nodes includes depositing and etching doped polysilicon.

14. The method of claim 12, wherein the ohmic contact layers each include metal silicide.

15. The method of claim 11, wherein replacing the one-side edges of the sacrificial isolation layers with the supporters includes:
forming a linear opening that exposes one-side edges of the mold layers in the vertical stack and the one-side edges of the sacrificial isolation layers;
recessing portions of the sacrificial isolation layers from the linear opening to form supporter openings between the one-side edges of the mold layers in the vertical stack; and
forming supporter materials that fill the supporter openings.

16. The method of claim 11, wherein the supporters and the sacrificial isolation layers include different materials.

17. The method of claim 11, wherein replacing the sacrificial isolation layers with the inter-cell dielectric layers includes:
stripping the sacrificial isolation layers using the supporters as a barrier to form inter-body sheet openings that expose the body sheets and inter-horizontal sheet openings that expose the horizontal sheets; and
forming the inter-cell dielectric layers that fill the inter-body sheet openings.

18. The method of claim 11, further comprising, before forming the first conductive lines, forming a first spacer surrounding tapered profiles disposed between the horizontal sheets and the body sheets.

19. The method of claim 11, wherein forming the protruding sheet nodes includes:
forming a second spacer that exposes the protruding edges and surrounds portions of the horizontal sheets;
cutting the protruding edges; and
horizontally recessing the second spacer to form the protruding sheet nodes.

20. The method of claim 11, further comprising:
after forming the second conductive lines,
forming tapered sheets by horizontally recessing the body sheets;
forming second contact nodes on the tapered sheets; and
forming data storage elements on the second contact nodes.
